(19) United States
(12) Patent Application Publication
(10) Pub. No.: US 2008/0241738 A1
(43) Pub. Date: Oct. 2, 2008

(54) LITHOGRAPHIC PRINTING PLATE PRECURSOR AND PRINTING METHOD

(75) Inventor: Kazuo MAEMOTO, Shizuoka (JP)

Correspondence Address: SUGHRUE-265550, 2100 PENNSYLVANIA AVE. NW, WASHINGTON, DC, 20037-3213, US

(73) Assignee: FUJIFILM CORPORATION, Tokyo (JP)

(21) Appl. No.: 12/054,448

(22) Filed: Mar. 25, 2008

(30) Foreign Application Priority Data
Mar. 27, 2007 (JP) 2007-082229

(51) Int. Cl. G03F 7/004; G03F 7/12

(52) U.S. Cl. 430/270.1; 430/302

(57) ABSTRACT

A lithographic printing plate precursor includes: a support; and an ink-receptive layer which contains a particle of an organic polymer and a compound comprising a fluorine atom, or contains a particle of an organic polymer containing a fluorine atom.

### FIELD OF THE INVENTION

The present invention relates to a lithographic printing plate precursor and a printing method. More particularly, it relates to a lithographic printing plate precursor for forming an image with inkjet ink by an inkjet recording system on a support to form a printing ink-receptive area and a printing method using the same.

### BACKGROUND OF THE INVENTION

As a recording system for forming an image on a recording medium based on image data signals, there are an electrophotographic system, a thermal transfer system and an inkjet system. The electrophotographic system is a complex system and an apparatus therefor is expensive because it requires such a process that an electrostatic latent image is formed on a photoreceptor drum through charge and exposure. Since the thermal transfer system uses an ink ribbon, it involves generation of a waste material of the ink ribbon which has not been used in the transfer and a high running cost, although an apparatus therefor itself is inexpensive. In the inkjet system, on the other hand, image formation is carried out with an inexpensive apparatus in such a manner that an ink is directly ejected to only a necessary image area on a recording medium so that the waste material does not generate and the running cost is low, and thus it is excellent as the recording system.

The recording medium for use in the inkjet recording system includes a broad range of materials, for example, paper, plastic or metal and is selected in accordance with the intended use. For instance, a printed material can be directly obtained by recording an image on plain paper, for example, high-quality paper or recycled paper. However, the inkjet recording system takes a lot of time for obtaining a large number of printed materials because of low recording speed. Thus, attempts for preparing a printing plate by the inkjet recording system and obtaining a large number of printed materials using the printing plate thus-prepared have been made. For instance, a technique wherein an image is drawn by supplying ink according to the inkjet recording system on a direct drawing type lithographic printing plate precursor comprising an aluminum support having provided thereon an ink-receptive layer containing an organic polymer compound is proposed (see, for example, JP-A-2000-108537 (the term “JP-A” as used herein means an “unexamined published Japanese patent application”)). Also, a method wherein a printing plate precursor having an ink-receptive layer capable of being removed with dampening water and/or printing ink is subjected to ejection of inkjet ink containing a dissolution-inhibiting compound which inhibits the dissolution of the ink-receptive layer with dampening water and/or printing ink, mounted on a printing machine and supplied with dampening water and/or printing ink to form an image is described (see, for example, JP-A-2003-94597 (corresponding to EP1266750A1)). Further, a method of producing a lithographic printing plate comprising a step wherein a solvent droplet is ejected on a receiving material comprising a substrate having provided thereon a hydrophilic image-forming layer containing an oleophilic polymer particle to dissolve the polymer particle thereby converting the hydrophilic image-forming layer to oleophilic is described (see, for example, JP-A-2004-216634). However, these methods have a problem in that blur of the ink ejected by inkjet occurs.

Moreover, methods of producing a lithographic printing plate by applying a specific ink to a support subjected to a surface treatment with an alkyl-terminated silicon-based or fluorine-base surfactant are disclosed (see, for example, U.S. Pat. No. 6,472,045, U.S. Pat. No. 6,455,132, U.S. Pat. No. 6,451,413, U.S. Pat. No. 6,555,205, U.S. Pat. No. 6,471,349 and U.S. Pat. No. 6,742,886). However, these methods have problems in that interference of ink droplet impact occurs, printing durability is poor and printed materials tend to be stained, although the blur of the ink ejected by inkjet is prevented.

### SUMMARY OF THE INVENTION

An object of the present invention is to provide a direct drawing type lithographic printing plate precursor which is prevented form the blur of ink and the interference of ink droplet impact when the lithographic printing plate precursor is ejected with inkjet ink by an inkjet recording system and which satisfies stain resistance at printing and a printing method using the lithographic printing plate precursor.

As a result of the intensive investigations, the inventors have found that the above-described object can be achieved by providing a specific ink-receptive layer containing a fluorine atom on a support. It has also been found that a large effect can be particularly obtained by incorporating a fluorine atom into a particle of an organic polymer.

Further, it has been found that when the ink-receptive layer containing a fluorine atom is developed with dampening water and/or printing ink on a printing machine, stain is apt to occur at printing, and it is preferred to develop with an aqueous solution containing a surfactant and/or hydrophilic resin before printing.

The present invention includes the following items.
(1) A lithographic printing plate precursor comprising a support and an ink-receptive layer containing a particle of an organic polymer and a compound including a fluorine atom.
(2) A lithographic printing plate precursor comprising a support having thereon an ink-receptive layer containing a particle of an organic polymer including a fluorine atom.
(3) The lithographic printing plate precursor as described in (1) or (2) above, wherein the support is an aluminum support having a hydrophilic surface.
(4) The lithographic printing plate precursor as described in any one of (1) to (3) above, wherein the ink-receptive layer comprises both a particle of an organic polymer including a fluorine atom and a particle of an organic polymer not including (being free from) a fluorine atom.
(5) A lithographic printing plate precursor comprising a support having thereon an ink-receptive layer comprising a layer containing a particle of an organic polymer not including (being free from) a fluorine atom and a layer containing a particle of an organic polymer including a fluorine atom in this order.
(6) A printing method comprising ejecting imagewise inkjet ink by an inkjet recording system on the lithographic printing plate precursor as described in any one of (1) to (5) above, subjecting an area not ejected with the inkjet ink of the ink-receptive layer to development to prepare a lithographic printing plate, mounting the lithographic printing plate on a printing machine and printing by supplying printing ink and dampening water, wherein the development of the area not ejected with the inkjet ink of the ink-receptive layer is performed with an aqueous solution containing a surfactant and/or hydrophilic resin.

According to the present invention, a lithographic printing plate precursor which is prevented form the blur of ink and the interference of ink droplet impact and which satisfies stain resistance at printing by providing a specific ink-receptive layer containing a fluorine atom on a support and a printing method using the lithographic printing plate precursor are provided.

### BRIEF DESCRIPTION OF THE DRAWINGS

FIG. 1 is an illustration showing the equipment for conducting the mechanical surface roughening treatment used in the example.

FIG. 2 is a graph showing the trapezoidal wave form of an alternating current source for use in the electrochemical surface roughening treatment.

FIG. 3 is a view showing the electrolytic bath for use in the invention.

FIG. 4 is an illustration showing the equipment for conducting the anodic oxidation treatment used in the example.

### DESCRIPTION OF REFERENCE NUMERALS AND SIGNS

11: Aluminum plate
12: Radial drum roller
13a, 13b: Main electrode
14: Electrolyte
15: Electrolyte supplying opening
16: Slit
17: Electrolyte passage
18: Auxiliary cathode
19a, 19b: Thyristor
20: Alternating current source
40: Main electrolytic bath
50: Auxiliary cathode bath
416: Aluminum plate
422: Conveying roller
420: Anode
430: Cathode
434: Power supply

### DETAILED DESCRIPTION OF THE INVENTION

The invention will be described in more detail below.

### [Support]

The lithographic printing plate precursor, specifically, direct drawing type lithographic printing plate precursor (recording medium) according to the invention is prepared by forming a specific ink-receptive layer on an appropriate support (substrate). The support (substrate) for use in the lithographic printing plate precursor is not particularly limited as long as it is a dimensionally stable plate-like material having necessary strength and durability. Example thereof include paper, paper laminated with plastic (for example, polyethylene, polypropylene or polystyrene), a metal plate (for example, aluminum, zinc or copper plate), a plastic film (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate or polyvinyl acetal film), paper or a plastic film laminated or deposited with metal.

Among them, in the invention, a polyester film or an aluminum plate is preferable, and an aluminum plate is particularly preferable because it has good dimensional stability and is relatively inexpensive. A preferable aluminum plate is a pure aluminum plate or an alloy plate which is mainly composed of aluminum and contains a trace amount of hetero elements. A plastic film laminated or deposited with aluminum may also used. The hetero element contained in the aluminum alloy includes, for example, silicon, iron, manganese, copper, magnesium, chromium, zinc, bismuth, nickel and titanium. The content of the hetero element in the aluminum alloy is at most about 10% by weight. An aluminum plate subjected to a surface treatment and a polyester film having provided thereon a sol-gel hydrophilic layer is preferably used as the support in the invention. These supports are described in detail below.

### [Aluminum Support]

Although pure aluminum is particularly preferred as aluminum in the invention, since completely pure aluminum is difficult to be produced in view of the refining technique, the aluminum plate may slightly contain the hetero element.

The composition of the aluminum plate for use in the invention is not specified and aluminum plates having materials conventionally known and used can be appropriately utilized. The thickness of the aluminum plate for use in the invention is ordinarily from about 0.1 to about 0.6 mm, preferably from 0.15 to 0.4 mm, particularly preferably from 0.15 to 0.3 mm.

The aluminum plate may be subjected to a surface treatment, for example, a surface roughening treatment or an anodic oxidation treatment, if desired. The surface treatment will be briefly described below.

Prior to the surface roughening of the aluminum plate, a degreasing treatment, for example, with a surfactant, an organic solvent or an aqueous alkaline solution is conducted for removing rolling oil on the surface thereof, if desired. The surface roughening treatment of the surface of the aluminum plate is conducted by various methods and includes, for example, a method of mechanically roughening the surface, a method of electrochemically dissolving and roughening the surface and a method of chemically dissolving the surface selectively. As the method of the mechanical surface roughening treatment, a known method, for example, a ball grinding method, a brush grinding method, a blast grinding method or a buff grinding method can be used. The electrochemical surface roughening treatment method includes, for example, a method of conducting it in an electrolyte of hydrochloric acid or nitric acid using alternating current or direct current. Also, a method of using a combination of both methods as described in JP-A-54-63902 can be used.

### <Detailed Description of Surface Treatment for Forming Grained Profile on Surface of Aluminum Plate>

The lithographic printing plate precursor according to the invention comprises an aluminum plate having the grained profile described above on the surface thereof formed by subjecting the aluminum plate the surface treatment described hereinafter and a specific layer provided thereon. A support which serves as a substrate of the lithographic printing plate precursor according to the invention is obtained by subjecting an aluminum plate to the surface roughening treatment and the anodic oxidation treatment, but the production process of the support is not particularly limited and may include various processes other than the surface roughening treatment and the anodic oxidation treatment. Examples of the typical method for forming the grained profile described above on the surface of the support include: a method to subject an aluminum plate sequentially to a mechanical surface roughening treatment, an alkali etching treatment, a desmut treatment with an acid and an electrochemical surface roughening treatment with an electrolyte; a method to subject an aluminum plate sequentially to a mechanical surface roughening treatment, an alkali etching treatment, a desmut treatment with an acid and plural times of electrochemical surface roughening treatment with different electrolytes; a method to subject an aluminum plate sequentially to an alkali etching treatment, a desmut treatment with an acid and an electrochemical surface roughening treatment with an electrolyte; and a method to subject an aluminum plate sequentially to an alkali etching treatment, a desmut treatment with an acid and plural times of electrochemical surface roughening treatment with different electrolytes, but the invention should not be construed as being limited thereto. In these methods, after the electrochemical surface roughening treatment, an alkali etching treatment and a desmut treatment with an acid may further be conducted. The aluminum support for the lithographic printing plate precursor according to the invention obtained by each of these methods has a grained profile including superimposed two or more irregularities of different cycles on the surface thereof so that it is excellent in both stain resistance and printing durability when it is used as a lithographic printing plate. Each process of the surface treatment is described in detail below.

### <Mechanical Surface Roughening Treatment>

The mechanical surface roughening treatment is an effective means for surface roughening treatment because it can form a surface having irregularities of an average wavelength of 5 to 100 μm at a low cost in comparison with an electrochemical surface roughening treatment. As a method for the mechanical surface roughening treatment, for example, a wire brush graining method to scratch an aluminum surface with a metal wire, a ball graining method to grain an aluminum surface with a abrasive ball and an abrasive, or a brush graining method to grain an aluminum surface with a nylon brush and an abrasive described in JP-A-6-135175 and JP-B-50-40047 (the term “JP-B” as used herein means an “examined Japanese patent publication”) can be used. Also, a transfer method to press an irregularity surface against an aluminum plate may also be used. Specifically, methods described in JP-A-55-74898, JP-A-60-36195 and JP-A-60-203496, and a method characterized by performing plural times of transfer described in JP-A6-55871, and a method characterized by using an elastic surface described in Japanese Patent Application No. 4-204235 (JP-A-6-24168) may also be used.

Further, a method to repeatedly perform transfer using a transfer roll with fine irregularities etched, for example, by electric discharge, shot blast, laser or plasma etching, or a method to contact an irregular surface having fine particles coated with an aluminum plate and apply a pressure repeatedly onto the surface to repeatedly transfer the irregularity pattern corresponding to the average diameter of the fine particles to the aluminum plate is also used. In order to impart the fine irregularities to a transfer roll, known methods described in JP-A-3-8635, JP-A-3-66404 and JP-A-63-65017 can be used. Alternatively, the roll surface may be formed with fine grooves in two directions using, for example, a dice, bite or laser to form rectangular irregularities on the surface. The roll surface may be subjected to known etching treatment or the like to round off the formed rectangular irregularities. Further, quenching, hard chromium plating or the like may be performed for increasing the hardness of the surface. Other examples of the mechanical surface roughening treatment include methods described in JP-A-61-162351 and JP-A-63-104889. In the invention, the above-described methods may be used in combination with each other in view of productivity or the like. The mechanical surface roughening treatment is preferably performed before the electrochemical surface roughening treatment.

The brush graining method preferably used in the mechanical surface roughening treatment is described below. The brush graining method is ordinarily performed by scrubbing one surface or both surfaces of the aluminum plate with a rotating brush roller comprising a cylindrical body whose surface is implanted with a plenty of synthetic resin bristles made, for example, of nylon (trade name), propylene or vinyl chloride, while spraying a slurry containing an abrasive over the rotating brush roller. An abrasive roller which is a roller having an abrasive layer on its surface may be used in place of the combination of the brush roller and slurry. In case of using the brush roller, a bend elastic constant of the brush bristle is preferably from 10,000 to 40,000 kg/cm² (0.98 to 3.92 GPa), more preferably from 15,000 to 35,000 kg/cm², and a bristle elasticity of the brush bristle is preferably 500 g or less, more preferably 400 g or less. The diameter of the brush bristle is ordinarily from 0.2 to 0.9 mm. The length of the brush bristles can be appropriately determined in accordance with the outside diameter of the brush roller and the diameter of the cylinder, and it is ordinarily from 10 to 100 mm.

As the abrasive, a known abrasive can be used. An abrasive, for example, pumice stone, silica sand, aluminum hydroxide, alumina powder, silicon carbide, silicon nitride, volcanic ash, carborundum or emery or a mixture thereof can be used. Among them, pumice stone and silica sand are preferable.

In particular, the silica sand is preferable because it is harder and less fragile than the pumice stone so that it is excellent in the surface roughening efficiency. The average particle diameter of the abrasive is preferably from 3 to 50 μm, more preferably from 6 to 45 μm, for achieving the excellent surface roughening efficiency and the reduced graining pitch. The abrasive is used, for example, by suspended in water to form a slurry liquid. In addition to the abrasive, the slurry liquid may contain, for example, a thickener, a dispersant (e.g., a surfactant) or a preservative. The specific gravity of the slurry liquid is preferably from 0.5 to 2.

An equipment suitable for the mechanical surface roughening treatment includes, for example, an equipment described in JP-B-50-40047.

### <Electrochemical Surface Roughening Treatment>

In the electrochemical surface roughening treatment, an electrolyte for use in conventional electrochemical surface roughening treatment using alternating current can be employed. In particular, a characteristic irregularity structure can be formed on the surface by using an electrolyte mainly composed of hydrochloric acid or nitric acid. The electrolytic surface roughening treatment according to the invention is preferably performed by conducting the first and second electrolytic treatments using alternating waveform current in an acidic solution before and after the cathodic electrolytic treatment. The cathodic electrolytic treatment generates hydrogen gas on the surface of the aluminum plate to form smut, which makes the surface state uniform and enables uniform electrolytic surface roughening during the subsequent electrolytic treatment using alternating waveform current. The electrolytic surface roughening treatment can be performed, for example, according to an electrochemical graining method (electrolytic graining method) described in JP-B-48-28123 and British Patent 896,563. The electrolytic graining method uses alternating current of sine waveform, but may be use a special waveform as described in JP-A-52-58602. The waveform described in JP-A-3-79799 may also be used. Methods described in JP-A-55-158298, JP-A-56-28898, JP-A-52-58602, JP-A-52-152302, JP-A-54-85802, JP-A-60-190392, JP-A-58-120531, JP-A-63-176187, JP-A-1-5889, JP-A-1-280590, JP-A-1-118489, JP-A-1-148592, JP-A-1-178496, JP-A-1-188315, JP-A-1-154797, JP-A-2-235794, JP-A-3-260100, JP-A-3-253600, JP-A-4-72079, JP-A-4-72098, JP-A-3-267400 and JP-A-1-141094 may be also used. In addition to the methods described above, the electrolysis can be performed using alternating current having a special frequency which is proposed as a production method of electrolytic condenser as described, for example, in U.S. Pat. Nos. 4,276,129 and 4,676,879.

Various electrolytic baths and power sources are proposed and those described in U.S. Pat. No. 4,203,637, JP-A-56-123400, JP-A-57-59770, JP-A-53-12738, JP-A-53-32821, JP-A-53-32822, JP-A-53-32823, JP-A-55-122896, JP-A-55-132884, JP-A-62-127500, JP-A-1-52100, JP-A-1-52098, JP-A-60-67700, JP-A-1-230800 and JP-A-3-257199 may be used. In addition, those described in JP-A-52-58602, JP-A-52-152302, JP-A-53-12738, JP-A-53-12739, JP-A-53-32821, JP-A-53-32822, JP-A-53-32833, JP-A-53-32824, JP-A-53-32825, JP-A-54-85802, JP-A-55-122896, JP-A-55-132884, JP-B-48-28123, JP-B-51-7081, JP-A-52-133838, JP-A-52-133840, JP-A-52-133844, JP-A-52-133845, JP-A-53-149135 and JP-A-54-146234 may be also used.

Examples of the acidic solution as the electrolyte include electrolytes described in U.S. Pat. Nos. 4,671,859, 4,661,219, 4,618,405, 4,600,482, 4,566,960, 4,566,958, 4,566,959, 4,416,972, 4,374,710, 4,336,113 and 4,184,932 in addition to nitric acid and hydrochloric acid.

The concentration of the acidic solution is preferably from 0.5 to 2.5% by weight, and is particularly preferably from 0.7 to 2.0% by weight considering the use thereof in the treatment for removing smut described above. The temperature of the solution is preferably from 20 to 80° C., more preferably from 30 to 60° C.

The aqueous solution mainly composed of hydrochloric acid or nitric acid can be used in the state of adding, to an aqueous hydrochloric acid or nitric acid solution having a concentration of 1 to 100 g/liter, at least one of nitric acid compound having a nitric acid ion, for example, aluminum nitride, sodium nitride or ammonium nitride or at least one of hydrochloric acid compound having an hydrochloric acid ion, for example, aluminum chloride, sodium chloride or ammonium chloride, at a concentration ranging from 1 g/liter to the saturated concentration thereof. Into the aqueous solution mainly composed of hydrochloric acid or nitric acid, a metal contained in an aluminum alloy, for example, iron, copper, manganese, nickel, titanium, magnesium or silica may be dissolved. It is preferable to use a solution wherein aluminum chloride, aluminum nitrate or the like is added to an aqueous hydrochloric acid or nitric acid solution having a concentration of 0.5 to 2% by weight so as to have concentration of aluminum ion of 3 to 50 g/liter.

Further, the addition of a compound capable of forming a complex with Cu enables uniform graining even on an aluminum plate containing a large amount of Cu. Examples of the compound capable of forming a complex with Cu include ammonia; an amine obtained by substituting a hydrogen atom of ammonia with a hydrocarbon group (for example, an aliphatic hydrocarbon group or an aromatic hydrocarbon group) or the like, for example, methylamine, ethylamine, dimethylamine, diethylamine, trimethylamine, cyclohexylamine, triethanolamine, triisopropanolamine or EDTA (ethylenediamine tetraacetic acid); and a metal carbonate, for example, sodium carbonate, potassium carbonate or potassium hydrogen carbonate. Other examples include an ammonium salt, for example, ammonium nitrate, ammonium chloride, ammonium sulfate, ammonium phosphate or ammonium carbonate. The temperature of the electrolyte is preferably from 10 to 60° C., more preferably from 20 to 50° C.

The alternating current wave used in the electrochemical surface roughening treatment is not particularly limited, and a sine wave, a rectangular wave, a trapezoidal wave, a triangular waver or the like is used. The rectangular wave and trapezoidal wave are preferable, and the trapezoidal wave is particularly preferable. The trapezoidal wave is a wave illustrated in FIG. 2. In this trapezoidal wave, the time (TP) necessary for the electric current to reach from zero to a peak is preferably from 1 to 3 msec. When the TP is less than 1 msec, a treatment-unevenness called a chatter mark generated perpendicularly in the traveling direction of the aluminum plate is apt to occur. When the TP exceeds 3 msec, in particular, in the case of using the nitric acid electrolyte, a trace component (as typified by an ammonium ion) which increases naturally in the electrolyte in the electrolytic treatment may adversely affects on the formation of uniform graining. As a result, when the plate is used to form a lithographic printing plate, the stain resistance thereof tends to decrease.

The trapezoidal wave alternating current having a duty ratio of 1:2 to 2:1 may be used. However, in an indirect power feeding system which uses no conductor roll for aluminum as described in JP-A-5-195300, that having a duty ratio of 1:1 is preferable. Although the trapezoidal wave alternating current having a frequency of 0.1 to 120 Hz may be used, that having a frequency of 50 to 70 Hz is preferable for the facilities. When the frequency is lower than 50 Hz, a main carbon electrode is readily dissolved, whereas when it is higher than 70 Hz, the influence of the inductance components on the power source is apt to occur, which results in increase in the power source cost.

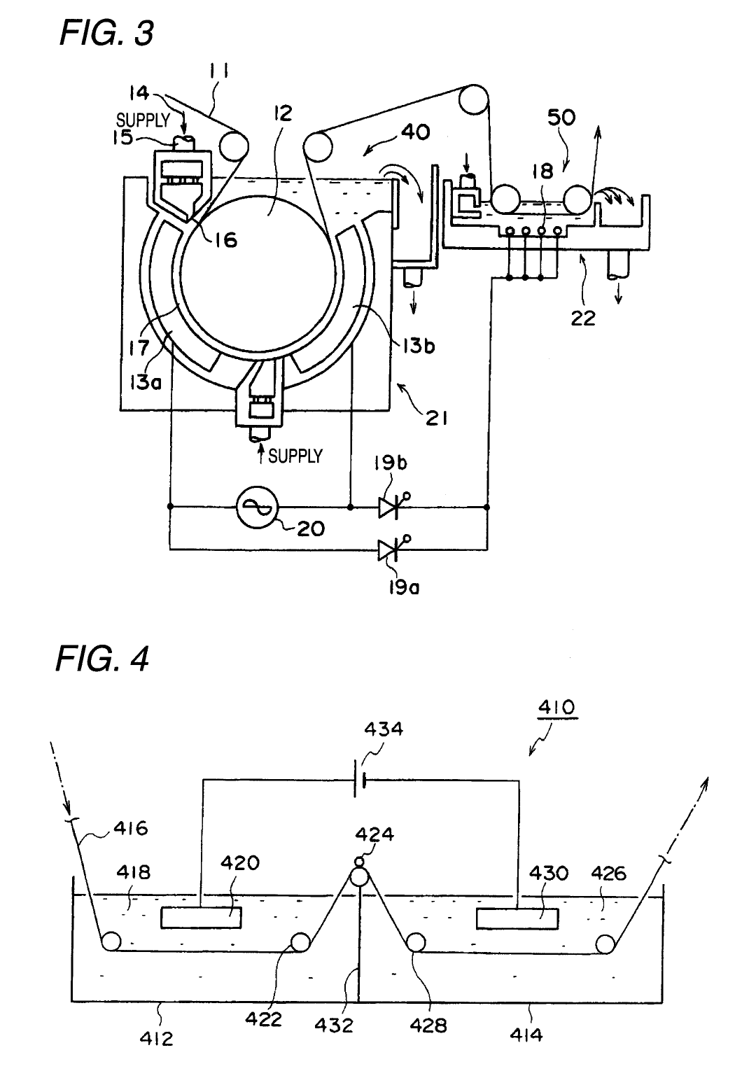

One or more alternating current sources can be connected to the electrolytic bath. In order to control the current ratio between anode and cathode components of the alternating current applied to the aluminum plate, which is opposite to a main electrode, thereby attaining uniform graining and dissolving carbon of the main electrode, it is preferable to place an auxiliary anode to cause a part of the alternating current to flow dividedly into the auxiliary anode, as illustrated in FIG. 3. In FIG. 3, 11 represents an aluminum plate, 12 represents a radial drum roller, 13a and 13b each represents a main electrode, 14 represents an electrolyte, 15 represents an electrolyte supplying opening, 16 represents a slit, 17 represents an electrolyte passage, 18 represents an auxiliary cathode, 19a and 19b each represents a thyristor, 20 represents an alternating current source, 40 represents a main electrolytic bath and 50 represents an auxiliary cathode bath. By dividing the electric current to cause a part thereof to flow, through a rectifying element or switching element, as a direct current into the auxiliary electrode, which is provided in a bath different from the bath for the two main electrodes, it is possible to control the ratio between the current value for taking charge of anodic reaction caused on the aluminum plate opposite to the main electrodes and the current value for taking charge of cathodic reaction. On the aluminum plate opposite to the main electrodes, the ratio of the electric quantity for the anodic reaction to that for the cathodic reaction (i.e., the ratio of the electric quantity in the cathodic reaction time/the electric quantity in the anodic reaction time) is preferably from 0.3 to 0.95.

As the electrolytic bath, a known electrolytic bath used in surface treatment, for example, a bath of a vertical type, a flat type, a radial type or the like may be used. A radial type electrolytic bath as described in JP-A-5-195300 is particularly preferable. The electrolyte passed in the electrolytic bath may be in parallel to or opposite to the traveling direction of the aluminum plate.

### (Nitric Acid Electrolysis)

The electrochemical surface roughening treatment using an electrolyte mainly composed of nitric acid can form pits having an average aperture size of 0.5 to 5 μm. When the electric quantity is relatively high, the electrolysis reaction is concentrated to generate also a honeycomb pit larger than 5 μm. In order to obtain such grain, the total of the electric quantity used for the anodic reaction of the aluminum plate at the point when the electrolysis reaction is completed is preferably from 1 to 1,000 C/dm², more preferably from 50 to 300 C/dm², and the electric current density at that point is preferably from 20 to 100 A/dm². When a nitric acid electrolyte of high concentration or high temperature is used, a small wave structure having an average aperture size of 0.2 μm or less can be formed.

### (Hydrochloric Acid Electrolysis)

Since hydrochloric acid has a high dissolution power for aluminum, it can form a fine irregularity on an aluminum surface by the application of slight electrolysis. Such a fine irregularity has an average aperture size of 0.01 to 0.2 μm, and is uniformly formed on the entire surface of an aluminum plate. In order to obtain such a grain, the total of the electric quantity used for the anodic reaction of the aluminum plate at the point when the electrolysis reaction is completed is preferably 1 from to 100 C/dm², more preferably from 20 to 70 C/dm², and the electric current density at that point is preferably 20 to 50 A/dm².

In the electrochemical surface roughening treatment using the electrolyte mainly composed of hydrochloric acid, a large undulation in a crater form can be simultaneously formed by making the total electric quantity for taking charge of the anodic reaction as large as a value ranging from 400 to 1000 C/dM². In this case, a fine irregularity having an average aperture size of 0.01 to 0.4 μm superimposed onto the crater undulation having an average aperture size of 10 to 30 μm is formed in the entire surface.

The aluminum plate is preferably subjected to a cathodic electrolytic treatment between the first and second electrolytic surface roughening treatments performed in an electrolyte, for example, a nitric acid or hydrochloric acid electrolyte. The cathodic electrolytic treatment forms smut on the surface of the aluminum plate and at the same time generates hydrogen gas, which allows more uniform electrolytic surface roughening treatment. The cathodic electrolytic treatment is performed in an acidic solution at a cathodic electric quantity of preferably from 3 to 80 C/dm², more preferably from 5 to 30 C/dm². The cathodic electric quantity of less than 3 C/dm² is not favorable because it may cause the shortage of smut deposition. The cathodic electric quantity exceeding 80 C/dm² is also not favorable because it may cause excessive smut deposition. The electrolyte may be same as or different from the solution used in the first and second electrolytic surface roughening treatments.

### <Alkali Etching Treatment>

The alkali etching treatment is a treatment for bringing the aluminum plate into contact with an alkali solution to dissolve the surface layer thereof.

The purpose of the alkali etching treatment performed before the electrolytic surface roughening treatment is, when no mechanical surface roughening treatment has been conducted, to remove a rolling oil, stain, natural oxidation film or the like from the surface of the aluminum plate (rolled aluminum), and when the mechanical surface roughening treatment has been performed, to dissolve the edge of the irregularity formed by the mechanical surface roughening treatment to modify the surface with steep irregularity into a surface having a smooth undulation.

In the case of conducting no mechanical surface roughening treatment before the alkali etching treatment, the etching amount is preferably from 0.1 to 10 g/m², more preferably from 1 to 5 g/m². When the etching amount is less than 0.1 g/m², since the rolling oil, stain, natural oxidation film or the like on the surface of the aluminum plate may remain, a uniform pit can not be formed and unevenness may occur in the subsequent electrolytic surface roughening treatment. On the other hand, when the etching amount is from 0.1 to 10 g/m², the removal of the rolling oil, stain, natural oxidation film or the like on the surface of the aluminum plate is sufficiently performed. The etching amount exceeding the above range is economically disadvantageous.

In the case of conducting the mechanical surface roughening treatment before the alkali etching treatment, the etching amount is preferably from 3 to 20 g/m², more preferably from 5 to 15 g/m². When the etching amount is less than 3 g/m², the irregularity formed by the mechanical surface roughening treatment may not be made smooth. Thus, in the subsequent electrochemical surface roughening treatment, a uniform pit may not be formed. Additionally, stain resistance may deteriorate at the time of printing. On the other hand, when the etching amount is more than 20 g/m², the irregularity structure may disappear.

The purposes of the alkali etching treatment performed immediately after the electrolytic surface roughening treatment are to dissolve smut formed in the acidic electrolyte, and to dissolve the edge of the pit formed by the electrolytic surface roughening treatment. Since the pit formed by the electrolytic surface roughening treatment is varied by the type of the electrolyte, the optimum etching amount is varied. However, the etching amount in the alkali etching treatment performed after the electrolytic surface roughening treatment is preferably from 0.1 to 5 g/m². When a nitric acid electrolyte is used, the etching amount should be higher than the case when a hydrochloric acid electrolyte is used. When the electrolytic surface roughening treatment is multiply conducted, the alkali etching treatment may be performed after each treatment, if desired.

Examples of the alkali used in the alkali solution include caustic alkali and an alkali metal salt. Specific examples of the caustic alkali include caustic soda and caustic potassium. Specific examples of the alkali metal salt include an alkali metal silicate, for example, sodium metasilicate, sodium silicate, potassium metasilicate or potassium silicate; an alkali metal carbonate, for example, sodium carbonate or potassium carbonate; an alkali metal aluminate, for example, sodium aluminate or potassium aluminate; an alkali metal aldonate, for example, sodium gluconate or potassium gluconate; and an alkali metal hydrogen phosphate, for example, disodium hydrogen phosphate, dipotassium hydrogen phosphate, trisodium phosphate or tripotassium phosphate. A solution of a caustic alkali and a solution containing both of a caustic alkali and an alkali metal aluminate are preferable since the solutions have a high etching rate and are inexpensive. An aqueous caustic soda solution is particularly preferable.

The alkali concentration of the alkali solution can be decided depending on the etching amount, and is preferably from 1 to 50% by weight, more preferably from 10 to 35% by weight. In the case where an aluminum ion is dissolved in the alkali solution, the concentration of the aluminum ions is preferably from 0.01 to 10% by weight, more preferably from 3 to 8% by weight. The temperature of the alkali solution is preferably from 20 to 90° C. The time for the treatment is preferably from 1 to 120 seconds.

Examples of the method for bringing the aluminum plate into contact with the alkali solution include a method of passing the aluminum plate through a bath containing the alkali solution, a method of immersing the aluminum plate into a bath containing the alkali solution and a method of spraying the alkali solution onto the surface of the aluminum plate.

### <Desmut Treatment>

After the electrochemical surface roughening treatment or the alkali etching treatment, washing with an acid (desmut treatment) is conducted to remove the smudge (smut) remaining on the surface. Examples of the acid used include nitric acid, sulfuric acid, phosphoric acid, chromic acid, hydrofluoric acid, and hydrofluoroboric acid. The desmut treatment is conducted, for example, by bringing the aluminum plate into contact with an acidic solution of hydrochloric acid, nitric acid, sulfuric acid or the like having an acid concentration of 0.05 to 30% by weight (and containing 0.01 to 5% by weight of an aluminum ion). Examples of the method for bringing the aluminum plate into contact with the acidic solution include a method of passing the aluminum plate through a bath containing the acidic solution, a method of immersing the aluminum plate into a bath containing the acidic solution and a method of spraying the acidic solution onto the surface of the aluminum plate. In the desmut treatment, it is permissible to use, as the acidic solution, waste liquid of the aqueous solution mainly composed of nitric acid or the aqueous solution mainly composed of hydrochloric acid discharged in the electrochemical surface roughening treatment, or to use waste liquid of the aqueous solution mainly composed of sulfuric acid discharged in the anodic oxidation treatment described below. The liquid temperature in the desmut treatment is preferably from 25 to 90° C. The time for the treatment is preferably from 1 to 180 seconds. In the acidic solution used in the desmut treatment, aluminum and an aluminum alloy component may be dissolved.

The aluminum plate whose surface is roughened as described above is subjected to an alkali etching treatment and a neutralizing treatment, if desired. Thereafter, the aluminum plate is subjected to an anodic oxidation treatment, if desired, in order to improve the water retentivity or abrasion resistance of the surface. As the electrolyte used in the anodic oxidation treatment of the aluminum plate, various electrolytes which form a porous oxide film can be used. Sulfuric acid, phosphoric acid, oxalic acid, chromic acid or a mixed acid thereof is ordinarily used. The concentration of the electrolyte may be appropriately determined depending on the kind of the electrolyte.

Treatment conditions for the anodic oxidation cannot be generally specified since the conditions vary depending on the electrolyte used. However, an electrolyte concentration of 1 to 80% by weight, a liquid temperature of 5 to 70° C., a current density of 5 to 60 A/dm², a voltage of 1 to 100 V, and an electrolysis time of 10 seconds to 5 minutes are ordinarily appropriate. When the amount of the anodized film is less than 2.0 g/m², the non-image area of the lithographic printing plate is easily scratched so that a so-called “scratch stain”, resulting from ink adhesion to the scared area at printing, is apt to occur. After the anodic oxidation treatment, the aluminum surface may be subjected to hydrophilizing treatment with a silicate.

### <Silicate Treatment>

A first embodiment is characterized by having a silicate layer in a coating amount of 1.2 to 25 mg/m². The silicate layer is formed by the silicate treatment.

Hydrophilizing treatment using an aqueous solution of alkali metal silicate, for example, sodium silicate or potassium silicate can be performed in accordance with methods and procedures described in U.S. Pat. Nos. 2,714,066 and 3,181,461. Examples of the alkali metal silicate include sodium silicate, potassium silicate and lithium silicate. The aqueous solution of the alkali metal silicate may contain an appropriate amount of sodium hydroxide, potassium hydroxide, lithium hydroxide or the like. The aqueous solution of the alkali metal silicate may contain an alkaline earth metal salt or a salt of group 4 (Group IVA) metal. Examples of the alkaline earth metal salt include a nitrate, for example, calcium nitrate, strontium nitrate, magnesium nitrate or barium nitrate; a sulfate; a hydrochloride; a phosphate; an acetate; an oxalate; and a borate. Examples of the salt of group 4 (Group IVA) metal include titanium tetrachloride, titanium trichloride, potassium fluorotitanate, potassium titanium oxalate, titanium sulfate, titanium tetraiodide, zirconyl chloride, zirconium dioxide, zirconium oxychloride and zirconium tetrachloride. The alkaline earth metal salts and salts of group 4 (Group IVA) metal may be used individually or in combination of two or more thereof.

In the first embodiment, the amount of silicate deposited should be from 1.2 to 25 mg/m², preferably from 2.0 to 20.0 mg/m², more preferably 5.0 to 15.0 mg/m². When the amount of silicate deposited is 1.2 mg/m² or more, the blur of ink is restrained and the stain resistance is increased. When the amount of silicate deposited is 20.0 mg/m² or less, the resulting lithographic printing plate has favorable printing durability. The characteristics obtained by providing the silicate layer is not further improved even when the amount of silicate deposited is increased exceeding 25 mg/m², which is disadvantageous from the standpoint of cost. The silicate may be present on the anodized film in the form of a continuous layer or in the form of an island.

The amount of silicate is measured, for example, as the amount of Si atom (mg/m²) by a calibration curve method using an X-ray fluorescence analyzer. More specifically, the amount of Si atom can be measured from the peak height of Si—Kα spectrum, for example, using an X-ray fluorescence analyzer (RIX3000, produced by Rigakudenki Co., Ltd.) under following conditions.
Equipment: RIX3000, produced by Rigakudenki Co., Ltd.
X-ray tube: Rh
Measured spectrum: Si—Kα
Tube voltage: 50 kV
Tube current: 50 mA
Slit: COARSE
Spectroscopic crystal: RX4
Detector: F-PC
Analyzed area: 30 mmΦ
Peak position (2θ): 144.75 deg.
Background (2θ): 140.70 deg., 146.85 deg.
Integration time: 80 seconds/sample

### [Sol-Gel Hydrophilic Layer]

According to a second embodiment, before the formation of an ink-receptive layer, a hydrophilic layer surface containing a sol-gel structure is provided on the aluminum support.

In the invention, a sol-gel hydrophilic layer may be provided on a support (substrate) before the formation of an ink-receptive layer in the production of a lithographic printing plate precursor. The support is not particularly limited as long as it is a dimensionally stable plate-like material having necessary strength and durability. Example thereof include paper, paper laminated with plastic (for example, polyethylene, polypropylene or polystyrene), a metal plate (for example, aluminum, zinc or copper plate), a plastic film (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate or polyvinyl acetal film), paper or a plastic film laminated or deposited with the metal described above.

The composition of the sol-gel hydrophilic layer is described below.

### <Hydrophilic Binder>

The sol-gel hydrophilic layer according to the invention contains a hydrophilic binder. The hydrophilic binder is preferably a sol-gel convertible material comprising a system of a metal hydroxide and a metal oxide, most preferably a sol-gel conversion system having a property of forming a gel structure of polysiloxane.

The binder serves as a dispersion medium for the constituting component of the hydrophilic layer, and is constructed so as to fulfill various purposes, for example, improvement in the physical strength of the layer, improvement in the dispersibility of the constituents of the layer, improvement in the coating property, improvement in the printing suitability and improvement in the convenience in the plate-making workability.

The content of the hydrophilic binder is preferably 30% by weight or more, more preferably in a range of 35 to 70% by weight, based on the total solid content of the hydrophilic layer. By controlling the content of the hydrophilic binder in the range described above, the hydrophilic layer having sufficient water resistance and abrasion resistance can be obtained.

As the hydrophilic polymer binder preferably used in the hydrophilic layer of the lithographic printing plate precursor according to the invention, an organic polymer compound for imparting adequate strength and surface hydrophilicity to the hydrophilic layer can be used. Specific examples thereof include a water-soluble resin, for instance, polyvinyl alcohol (PVA), modified PVA, for example, carboxy-modified PVA, starch and a derivative thereof, a cellulose derivative, for example, carboxymethyl cellulose or hydroxyethyl cellulose, casein, gelatin, polyvinyl pyrrolidone, vinyl acetate-crotonic acid copolymer, styrene-maleic acid copolymer, polyacrylic acid and a salt thereof, polyacrylamide and a water-soluble acrylic copolymer containing as a main constituting component, a water-soluble acrylic monomer, for example, acrylic acid or acrylamide.

Examples of the water resistant additive for crosslinking and curing the organic polymer compound include glyoxal, an initial condensate of aminoplast, for example, a melamine formaldehyde resin or a urea formaldehyde resin, a methylolated polyamide resin, a polyamide-polyamine-epichlorohydrin adduct, a polyamide-epichlorohydrin resin and a modified polyamide-polyimide resin. The water resistant additives may be used in combination with a crosslinking catalyst, for example, ammonium chloride or a silane coupling agent.

The system capable of undergoing the sol-gel conversion particularly preferably used in the invention is described in detail, for example, in Sumio Sakuhana, Sol-Gel Ho no Kagaku (Science of Sol-Gel Method), Agne Shofu Publishing Inc. (1988) and Ken Hirashima, Saishin Sol-Gel Ho niyoru Kinouseihakumaku Sakuseigijutu (Latest Technique for Preparing Functional Thin Film by Sol-Gel Method), Sogo Gijutu Center Co., Ltd. (1992).

Specifically, the system capable of undergoing the sol-gel conversion is a polymer material of resinous structure in which bonding groups of polyvalent element are bonded together through oxygen atom to form a network structure and simultaneously the polyvalent metal has a free hydroxyl group and/or alkoxy group. Thus, the system is in a sol state before coating when it contains many alkoxy groups and/or hydroxyl groups, while the network-like resinous structure is strengthened and the system turns into a gel state with the progress of the reaction for forming an ether bond after coating. Further, in addition to the property of changing the degree of hydrophilicity of the resin composition, a part of the hydroxyl groups are bonded to fine solid particles to modify the surface of the fine solid particles thereby also serving to change the degree of the hydrophilicity. Such a polyvalent bonding element in the compound having hydroxyl and alkoxy groups undergoing the sol-gel conversion includes, for example, aluminum, silicon, titanium and zirconium and either of which can be used in the invention. The sol-gel conversion system including siloxane bonds which can be most preferably used in the invention is described in detail below. Sol-gel conversion using aluminum, titanium or zirconium can be performed according to the following procedures described in connection with silicon by the substitution of the silicon with each of the elements.

The hydrophilic matrix formed through the sol-gel conversion is preferably a resin having a siloxane bond and a silanol group. The hydrophilic layer of the lithographic printing plate precursor of the invention is formed by coating of a coating solution of a sol system containing a silane compound having at least one silanol group and progress of the hydrolysis condensation of silanol groups as the elapse of time after coating to form a structure having a siloxane skeleton thereby proceeding gelation. The siloxane resin forming a gel structure is represented by formula (I) shown below, and the silane compound having at least one silanol group is represented by formula (II) shown below. The substance system, which changes from hydrophilic to hydrophobic, contained in the hydrophilic layer is not necessarily the silane compound represented by the formula (II) alone, but ordinarily may be an oligomer formed by a partial hydrolysis polymerization of the silane compound, or a mixed composition of the silane compound and the oligomer thereof.

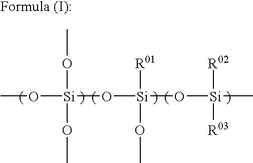

The siloxane resin represented by formula (I) is formed by sol-gel conversion from a dispersion solution containing at least one silane compound represented by formula (II). At least one of R⁰¹ to R⁰³ in formula (I) represents a hydroxy group, and the remainders each represents an organic residue selected from R⁰ and Y¹ in following formula (II).

(R⁰)ₙSi(Y¹)₄₋ₙ Formula (II)

Informula (II), R⁰ represents ahydroxy group, a hydrocarbon group or a heterocyclic group, Y¹ represents a hydrogen atom, a halogen atom, —OR¹¹, —OCOR¹² or —N(R¹³)(R¹⁴), wherein R¹¹ and R¹² each represents a hydrocarbon group, and R¹³ and R¹⁴, which may be the same or different, each represents a hydrogen atom or a hydrocarbon group, and n represents 0, 1, 2 or 3.

Examples of the hydrocarbon group or the heterocyclic group represented by R⁰ in formula (II) include a straight-chain or branched alkyl group having from 1 to 12 carbon atoms which may be substituted (for example, a methyl group, an ethyl group, a propyl group, a butyl group, a pentyl group, a hexyl group, a heptyl group, an octyl group, a nonyl group, a decyl group or a dodecyl group) wherein examples of the substitute arboxym a halogen atom (for example, a chlorine atom, a fluorine atom or a bromine atom), a hydroxy group, a thiol group, a carboxyl group, a sulfo group, a cyano group, an epoxy group, a —OR¹ group (wherein R¹ represents a methyl group, an ethyl group, a propyl group, a butyl group, a heptyl group, a hexyl group, an octyl group, a decyl group, a propenyl group, a butenyl group, a hexenyl group, an octenyl group, a 2-hydroxyethyl group, a 3-chloropropyl group, a 2-cyanoethyl group, a N,N-dimethylaminoethyl group, a 2-bromoethyl group, a 2-(2-methoxyethyl)oxyethyl group, a 2-methoxycarbonylethyl group, a 3-carboxypropyl group, a benzyl group), a —OCOR² group (wherein R² represents a group same as that defined for R¹), a —COOR² group, a —COR group, a —N(R³)(R³) group (wherein R³, which may be the same or different, each represents a hydrogen atom or a group same as that defined for R¹), a —NHCONHR² group, a —NHCOOR² group, a —Si(R²)₃ group, a —CONHR³ group and a —NHCOR² group, and one or more substituents may be present in the alkyl group; a straight-chain or branched alkenyl group having from 2 to 12 carbon atoms which may be substituted (for example, a vinyl group, a propenyl group, a butenyl group, a pentenyl group, a hexenyl group, an octenyl group, a decenyl group or a dodecenyl group), wherein the substituent is same as that for the alkyl group; an aralkyl group having from 7 to 14 carbon atoms which may be substituted (for example, a benzyl group, a phenethyl group, a 3-phenylpropyl group, a naphthylmethyl group or a 2-naphthylethyl group), wherein the substituent is same as that for the alkyl group, and one or more substituents maybe present in the aralkyl group; an alicyclic group having from 5 to 10 carbon atoms which may be substituted (for example, a cyclopentyl group, a cyclohexyl group, a 2-cyclohexylethyl group, a 2-cyclopentylethyl group, a norbornyl group or an adamantyl group), wherein the substituent is same as that for the alkyl group, and one or more substituents may be present in the alicyclic group; an aryl group having from 6 to 12 carbon atoms which may be substituted (for example, a phenyl group or a naphthyl group), wherein the substituent is same as that for the alkyl group, and one or more substituents may be present in the aryl group; and a heterocyclic group containing at least one atom selected from a nitrogen atom, an oxygen atom and a sulfur atom which may have a condensed ring or may be substituted (examples of the hetero ring including a pyran ring, a furan ring, a thiophene ring, a morpholine ring, a pyrrole ring, a thiazole ring, an oxazole ring, a pyridine ring, a piperidine ring, a pyrrolidone ring, abenzothiazole ring, a benzoxazole ring, a quinoline ring and a tetrahydrofuran ring), wherein the substituent is same as that for the alkyl group, and one or more substituents may be present in the heterocyclic group.

The OR¹¹ group, —OCOR¹² group and —N(R¹³)(R¹⁴) group represented by Y¹ in formula (II) each represents, for example, the following groups. In the —OR¹¹ group, R¹¹ represents an aliphatic group having from 1 to 10 carbon atoms which may be substituted (for example, a methyl group, an ethyl group, a propyl group, a butyl group, a heptyl group, a hexyl group, a pentyl group, an octyl group, a nonyl group, a decyl group, a propenyl group, a butenyl group, a heptenyl group, a hexenyl group, an octenyl, a decenyl group, a 2-hydroxyethyl group, a 2-hydroxypropyl group, a 2-methoxyethyl group, a 2-(methoxyethyloxo)ethyl group, a 2-(N,N-diethylamino)ethyl group, a 2-methoxypropyl group, a 2-cyanoethyl group, a 3-methyloxapropyl group, a 2-chloroethyl group, a cyclohexyl group, a cyclopentyl group, a cyclooctyl group, a chlorocyclohexyl group, a methoxycyclohexyl group, a benzyl group, a phenethyl group, a dimethoxybenzyl group, a methylbenzyl group or a bromobenzyl group).

In the OCOR¹² group, R¹² represents an aliphatic group same as that defined for R¹¹ or an aromatic group having from 6 to 12 carbon atoms which may be substituted, wherein examples of the aromatic group include the groups same as those described for the aryl group represented by R⁰ . In the —N(R¹³)(R¹⁴) group, R¹³ and R¹⁴, which may be the same or different, each represents a hydrogen atom or an aliphatic group having from 1 to 10 carbon atoms which may be substituted (for example, the groups same as those described for R¹¹ in the —OR¹¹ group). More preferably, the total number of carbon atoms included in R¹³ and R¹⁴ is 16 or less. Specific examples of the silane compound represented by formula (II) include the following compounds: tetrachlorosilane, tetrabromosilane, tetramethoxysilane, tetraethoxysilane, tetraisopropoxysilane, tetrabutoxysilane, methyl trichlorosilane, methyltribromosilane, methyltrimethoxysilane, methyltriethoxysilane, methyltriisopropoxysilane, methyltri-tert-butoxysilane, ethyltrichlorosilane, ethyltribromosilane, ethyltrimethoxysilane, ethyltriethoxysilane, ethyltriisopropoxysilane, ethyltri-tert-butoxysilane, n-propyltrichlorosilane, n-propyltribromosilane, n-propyltrimethoxysilane, n-propyltriethoxysilane, n-propyltriisopropoxysilane, n-propyltri-tert-butoxysilane, n-hexyl trichlorosilane, n-hexyltribromosilane, n-hexyltrimethoxysilane, n-hexyltriethoxysilane, n-hexyltriisopropoxysilane, n-hexyltri-tert-butoxysilane, n-decyltrichlorosilane, n-decyltribromosilane, n-decyltrimethoxysilane, n-decyltriethoxysilane, n-decyltriisopropoxysilane, n-decyltri-tert-butoxysilane, n-octadecyltrichlorosilane, n-octadecyltribromosilane, n-octadecyltrimethoxysilane, n-octadecyltriethoxysilane, n-octadecyltriisopropoxysilane, n-octadecyltri-tert-butoxysilane, phenyltrichlorosilane, phenyltribromosilane, phenyltrimethoxysilane, phenyltriethoxysilane, phenyltriisopropoxysilane, phenyltri-tert-butoxysilane, dimethoxydiethoxysilane, dimethyldichlorosilane, dimethyldibromosilane, dimethyldimethoxysilane, dimethyldiethoxysilane, diphenyldichlorosilane, diphenyldibromosilane, diphenyldimethoxysilane, diphenyldiethoxysilane, phenylmethyldichlorosilane, phenylmethyldibromosilane, phenylmethyldimethoxysilane, phenylmethyldiethoxysilane, triethoxyhydrosilane, tribromohydrosilane, trimethoxyhydrosilane, triisopropoxyhydrosilane, tri-tert-butoxyhydrosilane, vinyltrichlorosilane, vinyltribromosilane, vinyltrimethoxysilane, vinyltriethoxysilane, vinyltriisopropoxysilane, vinyltri-tert-butoxysilane, trifluoropropyltrichlorosilane, trifluoropropyltribromosilane, trifluoropropyltrimethoxysilane, trifluoropropyltriethoxysilane, trifluoropropyltriisopropoxysilane, trifluoropropyltri-tert-butoxysilane, γ-glycidoxypropylmethyldimethoxysilane, γ-glycidoxypropylmethyldiethoxysilane, γ-glycidoxypropyltrimethoxysilane, γ-glycidoxypropyltriethoxysilane, γ-glycidoxypropyltriisopropoxysilane, γ-glycidoxypropyltri-tert-butoxysilane, γ-methaacryloxypropylmethyldimethoxysilane, γ-methaacryloxypropylmethyldiethoxysilane, γ-methaacryloxypropyltrimethoxysilane, γ-methaacryloxypropyltriisopropoxysilane, γ-methaacryloxypropyltri-tert-butoxysilane, γ-aminopropylmethyldimethoxysilane, γ-aminopropylmethyldiethoxysilane, γ-aminopropyltrimethoxysilane, γ-aminopropyltriethoxysilane, γ-aminopropyltriisopropoxysilane, γ-aminopropyltri-tert-butoxysilane, γ-mercaptopropylmethyldimethoxysilane, γ-mercaptopropylmethyldiethoxysilane, γ-mercaptopropyltrimethoxysilane, γ-mercaptopropyltriethoxysilane, γ-mercaptopropyltriisopropoxysilane, γ-mercaptopropyltri-tert-butoxysilane, β-(3,4-epoxycyclohexyl)ethyltrimethoxysilane and β-(3,4-epoxycyclohexyl)ethyltriethoxysilane.

The silane compound represented by formula (II) used in the formation of the hydrophilic layer according to the invention may be used in combination with a metal compound, for example, a Ti, Zn, Sn, Zr or Al compound, which connects to the resin during sol-gel conversion to form a film. Examples of the metal compound include Ti(OR²)₄ (wherein R² represents, for example, a methyl group, an ethyl group, a propyl group, a butyl group, a pentyl group or a hexyl group), TiCl₄, Zn(OR²)₂, Zn(CH₃COCHCOCH₃)₂, Sn(OR²)₄, Sn(CH₃COCHCOCH₃)₄, Sn(OCOR²)₄, SnCl₄, Zr(OR²)₄, Zr(CH₃COCHCOCH₃)₄ and Al(OR²)₃.

The matrix having a gel structure may contain a hydrophilic polymer having a silane coupling group at the terminal of the main chain thereof or a crosslinking agent for the purposes of improving a physical property, for example, film strength or flexibility, improving a coating property and controlling a hydrophilicity.

Examples of the hydrophilic polymer having a silane coupling group at the terminal of the main chain thereof include a polymer represented by the following formula (1):

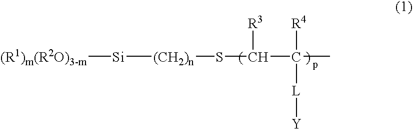

In the formula (1), R¹, R², R³ and R⁴ each represents a hydrogen atom or a hydrocarbon group having 8 or less carbon atoms, m represents 0, 1 or 2, n represents an integer of 1 to 8, and p represents an integer of 30 to 300. Y represents —NHCOCH₃, —CONH₂, —CON (CH₃)₂, —COCH₃, —OCH₃, —OH, —CO₂M or —CONHC(CH₃)₂SO₃M, and M represents one member selected from a group consisting of a hydrogen atom, an alkali metal, an alkaline earth metal and an onium.

L represents a single bond or an organic connecting group. The organic connecting group represents a polyvalent connecting group composed of a nonmetallic atom, and specifically is a group composed of 1 to 60 carbon atoms, 0 to 10 nitrogen atoms, 0 to 50 oxygen atoms, 1 to 100 hydrogen atoms and 0 to 20 sulfur atoms. More specific examples of the connecting group include the structural units shown below and groups constructed by combinations of these structural units.

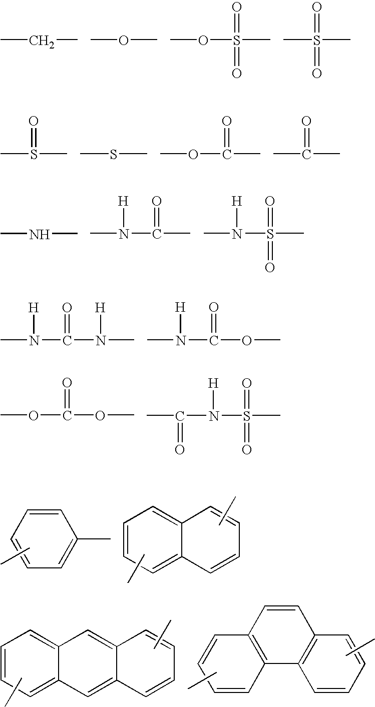

Specific examples of the hydrophilic polymer having a silane coupling group represented by formula (1) include the polymers shown below. In the following specific examples, p can be any number from 100 to 250.

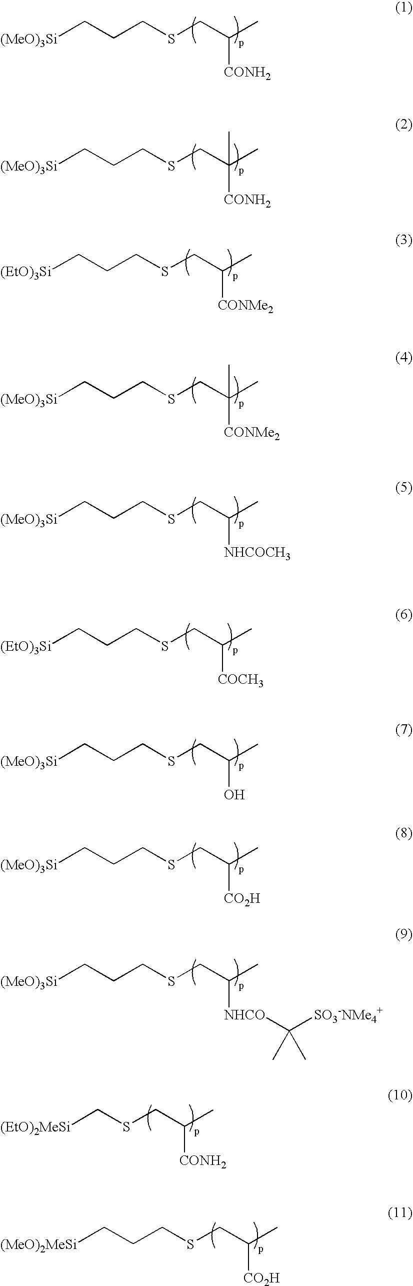

The hydrophilic polymer according to the invention can be synthesized by radical polymerization of a radical polymerizable monomer represented by formula (2) shown below and a silane coupling agent having a chain transfer function in the radical polymerization represented by formula (3) shown below. Since the silane coupling agent represented by formula (3) has a chain transfer function, a polymer having a silane coupling group at the terminal of the main chain can be synthesized in the radical polymerization.

R¹, R², R³, R⁴, L, Y, m and n in formulae (2) and (3) shown below have the same meanings as those in formula (1), respectively.

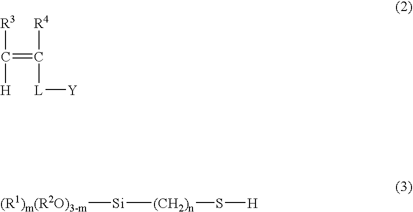

As described above, it is particularly preferable for the lithographic printing plate precursor according to the invention to provide the hydrophilic layer formed by a sol-gel method between the ink-receptive layer and the support.

### <Fine Inorganic Particle>

The sol-gel hydrophilic layer according to the invention may contain a fine inorganic particle for the purpose of improving the strength of the cured layer in the image area and the on-press development property in the non-image area.

Preferable examples of the fine inorganic particle include silica, alumina, magnesium oxide, titanium oxide, magnesium carbonate, calcium alginate and mixtures thereof.

The average particle size of the fine inorganic particle is preferably from 5 nm to 10 μm, more preferably from 0.5 to 3 μm. In the range described above, the particle is stably dispersed in the hydrophilic layer, sufficiently maintains the film strength and can form the non-image area excellent in hydrophilicity and prevented from the occurrence of stain at the printing.

The fine inorganic particle described above is easily available as a commercial product, for example, a colloidal silica dispersion.

The content of the fine inorganic particle is preferably 20% by weight or less, more preferably 10% by weight or less, based on the total solid content of the hydrophilic layer.

### <Formation of Sol-Gel Hydrophilic Layer>

The sol-gel hydrophilic layer is formed by dispersing or dissolving the necessary components described above in a solvent to prepare a coating solution and coating the solution. Examples of the solvent used include ethylene dichloride, cyclohexanone, methylethylketone, methanol, ethanol, propanol, ethylene glycol monomethyl ether, 1-methoxy-2-propanol, 2-methoxyethyl acetate, 1-methoxy-2-propyl acetate, dimethoxy ethane, methyl lactate, ethyl lactate, N,N-dimethylacetamide, N,N-dimethylformamide, tetramethylurea, N-methylpyrrolidone, dimethylsulfoxide, sulfolane, γ-butyrolactone, toluene and water, but the invention should not be construed as being limited thereto. These solvents may be used individually or as a mixture. The solid concentration of the coating solution is preferably from 1% to 50% by weight.

The sol-gel hydrophilic layer according to the invention may also be formed by preparing coating solutions by dispersing or dissolving the same or different components described above in the same or different solvents and conducting repeatedly plural coating and drying.

The sol-gel hydrophilic layer can be formed by coating the hydrophilic coating solution composition prepared in the manner described above on a surface of support, followed by drying. The layer thickness of the sol-gel hydrophilic layer can be determined in accordance with the intended use and ordinarily in a range from 0.5 to 5.0 g/m², preferably from 1.0 to 3.0 g/m², in terms of the coating amount after drying. The coating amount of less than 0.5 g/m² is not desirable because the effect of hydrophilicity is hardly exerted and the coating weight exceeding 5.0 g/m² is also not desirable because the deteriorate of film strength tends to occur.

### [Ink-Receptive Layer]

(1) According to one embodiment of the ink-receptive layer according to the invention, it contains a particle of an organic polymer and a compound including a fluorine atom.

(2) According to another embodiment of the ink-receptive layer according to the invention, it contains a particle of an organic polymer including a fluorine atom.

In the embodiment of (2), the ink-receptive layer may contain a compound including a fluorine atom in addition to the particle of an organic polymer including a fluorine atom.

The coating amount of the ink-receptive layer is preferably 0.1 g/m² or more. The coating amount of 0.1 g/m² or more exerts the preferable effect of the invention.

In the ink-receptive layer of the embodiment of (1), the amount of the particle of an organic polymer is ordinarily in a range from 100 to 5,000 mg/m², preferably from 500 to 4,000 mg/m², and the amount of the compound including a fluorine atom is ordinarily in a range from 10 to 1,000 mg/m², preferably from 20 to 500 mg/m².

In the ink-receptive layer of the embodiment of (2), the amount of the particle of an organic polymer including a fluorine atom is ordinarily in a range from 10 to 5,000 mg/m², preferably from 20 to 4,000 mg/m², and the amount of the compound including a fluorine atom is ordinarily in a range from 0 to 500 mg/m², preferably from 0 to 200 mg/M².

The total amount of fluorine atom included in the ink-receptive layer is ordinarily from 0.01 to 20% by weight, preferably from 0.5 to 10% by weight. The ratio of the components described above is controlled so as to achieve the range.

### (Particle of Organic Polymer)

The average particle size of the particle of an organic polymer is preferably from 10 to 2,000 nm, more preferably from 30 to 400 nm, most preferably from 50 to 300 nm. The particle of an organic polymer is preferably a particle of an organic polymer obtained by emulsion polymerization or a particle of an organic polymer obtained by a self-water dispersion. The average molecular weight of the particle of an organic polymer is preferably from 5,000 to 1,000,000. The introduction of a fluorine atom into the particle of an organic polymer as in the embodiment of (2) is preferably because the blur of inkjet ink impacted is prevented.

As the particle of an organic polymer, a mixture of a particle of an organic polymer including a fluorine atom and a particle of an organic polymer not including a fluorine atom. In this case, the amount of the particle of an organic polymer including a fluorine atom is preferably 5% by weight or more, more preferably 10% by weight or more, based on the total amount of the particle of an organic polymer.

The ink-receptive layer may have a multilayer structure. Specifically, a layer containing a particle of an organic polymer not including a fluorine atom is provided as an under layer and on the under layer, a layer containing a particle of an organic polymer including a fluorine atom is provided as an upper layer. In this case, the coating amount of the particle of an organic polymer not including a fluorine atom in the under layer is preferably 0.3 g/m² or more and the coating amount of the particle of an organic polymer including a fluorine atom in the upper layer is preferably 0.001 g/m² or more. More preferably, the coating amount of the particle of an organic polymer not including a fluorine atom in the under layer is from 0.5 to 5.0 g/m² and the coating amount of the particle of an organic polymer including a fluorine atom in the upper layer is from 0.01 to 1.0 g/m².

The particle of an organic polymer obtained by emulsion polymerization is described in detail below. The monomer for the emulsion polymerization is essentially a monomer capable of undergoing the emulsion polymerization and includes, for example, an acrylate monomer, a methacrylate monomer, an acrylamide monomer, a methacrylamide monomer, a styrene monomer, a vinyl monomer and an acrylonitrile monomer, each of which is capable undergoing vinyl polymerization.

Examples of the acrylate monomer and methacrylate monomer include methyl methacrylate, ethyl methacrylate, butyl methacrylate, allyl methacrylate, hydroxyethyl methacrylate, methacrylic acid, glycidyl methacrylate, 2-isocyanatoethyl methacrylate, methyl acrylate, ethyl acrylate, butyl acrylate, allyl acrylate, hydroxyethyl acrylate, acrylic acid, glycidyl acrylate and 2-isocyanatoethyl acrylate, but the invention should not be construed as being limited thereto.

Examples of the styrene monomer include styrene, α-methylstyrene, vinyltoluene, tert-butylstyrene and methoxymethylstyrene, but the invention should not be construed as being limited thereto.

Examples of the acrylamide monomer and methacrylamide monomer include acrylamide, methacrylamide, an alkylmethacrylamide, an alkylacrylamide and 2-acrylamido-2-methylpropanesulfonic acid (AMPS), but the invention should not be construed as being limited thereto.

Examples of the vinyl monomer include vinyl acetate, divinylbenzene, butadiene and isoprene, but the invention should not be construed as being limited thereto. Examples of the nitrile monomer include acrylonitrile and methacrylonitrile, but the invention should not be construed as being limited thereto. As other monomers, for example, maleic acid, maleic anhydride and a half eater of maleic acid are exemplified, but the invention should not be construed as being limited thereto.

The particle of an organic polymer including a fluorine atom according to the embodiment (2) can be obtained by copolymerization of a monomer formed by introducing a fluorine atom into the monomer described above. It also may be a homopolymer of the monomer including a fluorine atom. The monomer including a fluorine atom includes, for example, a monomer, for example, tetrafluoroethylene, hexafluoroethylene, trifluoroethylene, chlorotrifluoroethylene, fluorinated vinylidene or fluorinated vinyl as described in JP-A-1-247966 and a monomer represented by a structural formula (4) shown below described in JP-A-63-200065.

CH₂═CR₃COOR₄(CF₂)ₙCFA₂ (4)

In formula (4), R₃ represents a hydrogen atom or a lower alkyl group, and R₄ represents —(CH₂)ₘ— or

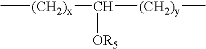

(wherein m represents an integer of 0 to 12, x+y=m′−1 (wherein m′ is from 2 to 12), and R₅ represents a hydrogen atom or an acetyl group), A independently represents a hydrogen atom, a fluorine atom or a —CF₃, and n represents an integer of 0 to 12.

The monomer represented by structural formula (4) is preferably represented by the following formula:

CH₂═CR₃COO(CH₂)ₘ(CF₂)ₙCF₃

CH₂═CR₃COO(CH₂)ₘ(CF₂)ₙCF₂H

CH₂═CR₃COO(CH₂)ₘ(CF₂)ₙCF(CF₃)₂

or

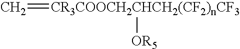

(wherein R₃, R₅, m and n have the same meaning as defined above, respectively), and it particularly preferably includes, for example, CH₂═C(CH₃)COOCH₂CF₃, CH₂═C(CH₃)COOCH₂(CF₂)₂H, CH₂═C(CH₃)COOCH₂(CF₂)₄H and CH₂═C(CH₃)COO(CH₂)₂ (CF₂)₈F.

The particle of an organic polymer according to the invention can be obtained by emulsion polymerization of each monomer described above in an aqueous medium using a radical polymerization initiator according to a conventional manner. As the polymerization initiator, for example, azobisisobutyronitrile, isobutyrylperoxide, octanoylperoxide, diisopropylperoxydicarbonate, or a fluorine-containing organic peroxide represented by formula [Cl(CF₂CFCl)₂CF₂COO]₂ or [X(CF₂CF₂)ₙCOO]₂ (wherein X represents a hydrogen atom, a fluorine atom or a chlorine atom) can be used. In particular, a persulfate, for example, ammonium persulfate, potassium persulfate or sodium persulfate, or a redox initiator of the persulfate with a thiosulfate, for example, sodium thiosulfate, potassium thiosulfate or sodium hydrogen thiosulfate, a sulfite, for example, sodium sulfite, potassium sulfite or sodium hydrogen sulfite, or a salt of transition metal, for example, iron (II) sulfate is preferably used.

For the purpose of increasing the thermal decomposition temperature or controlling the molecular weight distribution of the polymer obtained, a chain transfer agent, for example, a mercaptan may be used. In the case of using the chain transfer agent, the amount thereof added is ordinarily from 0.01 to 1 part by weight based on 100 parts by weight of the monomer.

The polymerization temperature is ordinarily in a range of 0 to 100° C., and it is determined in connection with decomposition temperature of the polymerization initiator used, and in many cases, the temperature ranging from 10 to 80° C. is preferably adopted.

In the polymerization, an emulsifier may not be used. As the emulsifier, a conventional hydrocarbon nonionic or ionic surfactant can be used and also a water-soluble fluorine-based surfactant can be used. For instance, a compound represented by formula (3) or (4) shown below and its salt are exemplified.

X(CF₂)ₙCOOH (3)

In formula (3), X represents a hydrogen atom, a chlorine atom or a fluorine atom, and n represents an integer of 6 to 12.

F(CF₂)ₘO[CF(X)CF₂O]ₙCF(X)COOH (4)

In formula (4), X each represents a fluorine atom or a lower perfluoroalkyl group, m represents an integer of 1 to 5, and n represents an integer of 0 to 10.

The particle of an organic polymer obtained by the self-water dispersion will be described below. The self-dispersible resin includes a salt of a synthetic resin having an acid value with a basic substance and a resin having a hydrophilic group, for example, a hydroxy group, as a substituent, and is preferably a self-dispersible resin comprising a synthetic resin having an acid value of 50 to 280 wherein a part of the acid is neutralized with a base in order to microparticulate the particle of an organic polymer and to impart hydrophilicity to the particle of an organic polymer. The anionic functional group which provides an acid value to a synthetic resin is not particularly restricted and includes a carboxyl group and a sulfonic acid group. The carboxyl group is ordinarily used and can form a preferable self-water dispersible thermoplastic resin particle.

The kind of resin in the self-water dispersible resin particle is not particularly restricted. In order to satisfy the conditions, for example, particulation of resin, film strength of the image area and hydrophilicity of the non-image area, a copolymer containing at least one monomer unit selected from styrene, a substituted styrene, for example, α-methylstyrene, an acrylate, for example, methyl acrylate, ethyl acrylate, butyl acrylate or 2-ethylhexyl acrylate and a methacrylate, for example, methyl methacrylate, ethyl methacrylate, butyl methacrylate or 2-ethylhexyl methacrylate and at least one monomer unit selected from acrylic acid and methacrylic acid is preferable. Also, copolymerization of a monomer containing a fluorine atom as described with respect to the emulsion polymerization is particularly preferable in view of preventing the blur of ink. The molecular weight of the resin is not particularly restricted and preferably from 1,000 to 100,000, in terms of weight average molecular weight.

The self-water dispersible resin particle according to the invention is different from a resin particle obtained by a known emulsion polymerization method or forcible emulsification of an oleophilic polymer with an emulsifier and is obtained by a phase inversion emulsification method which can easily provide a self-water emulsifiable resin particle inherently having hydrophilicity.

Specifically, in the first stage, a self-water dispersible resin is dissolved in an organic solvent and then added a prescribed amount of a base for neutralization to the solution. In the second stage, an excess amount of an aqueous medium is mixed with the resin solution prepared in the first stage to emulsify thereby obtaining an aqueous dispersion solution of the resin particle.

If desire, in the third stage, a solvent-removing process for removing the organic solvent used in the first stage may be performed in order to increase the dispersion stability of the resin particle dispersion solution. Further, it is preferred that after the completion of the process of the second stage or the process of third stage, a process for removing coarse resin particles, for example, by filtration with a filter or centrifugation is conducted.

As the organic solvent for dissolving the synthesis resin in the first stage, a solvent capable of dissolving the resin, for example, a ketone solvent, e.g., acetone, dimethyl ketone or methyl ethyl ketone, an alcohol solvent, e.g., methanol, ethanol or isopropanol, a chlorinated solvent, e.g., chloroform or methylene chloride, an aromatic solvent, e.g., benzene or toluene, an ester solvent, e.g., ethyl acetate, a glycol ether solvent, e.g., ethylene glycol monomethyl ether or ethylene glycol dimethyl ether or an amide solvent can be used. When the resin is an acrylic resin, a combination of at least one solvent selected from the ketone solvent and at least one solvent selected from the alcohol solvent is preferable.

The amount of the organic solvent used is not particularly restricted as long as the effects of the invention are achieved and is preferably from 1/1 to 1/20 in terms of the weight ratio of synthetic resin/organic solvent.

### (Compound Including Fluorine Atom)

The compound including a fluorine atom for use in the invention is preferably a compound having five or more fluorine atoms per molecule, more preferably an organic fluorine compound having five or more fluorine atoms, particularly preferably a compound having a perfluoroalkyl structure. When the particle of an organic polymer contains a particle of an organic polymer including a fluorine atom, the compound including a fluorine atom may not be used.

### [Organic Fluorine Compound Having Five or More Fluorine Atoms]

The organic fluorine compound which can be used in the invention preferably has five or more fluorine atoms per molecule or per constituting unit in case of the polymer compound. By fulfilling such a condition, the effect of preventing the blur of ink is more increased. The organic fluorine compound is preferably water soluble, and also preferably a compound having a surface active effect.

A preferable organic fluorine compound according to the invention is represented by formula R_{F}-Rₚₒₗ, wherein R_{F} represents a straight-chain or branched fluoroalkyl group having 3 or more carbon atoms, and Rₚₒₗ represents a polar group, for example, a carboxylic acid or a salt thereof, a sulfonic acid or a salt thereof, a phosphoric acid or a salt thereof, a phosphonic acid or a salt thereof, an amino group or a salt thereof, a quaternary ammonium salt, a polyethyleneoxy skeleton, a polypropyleneoxy skeleton, a sulfonamido group, an ether group or a betaine structure. Among them, those having a sulfoxyl group or a salt thereof are more preferable because they hardly interact with a silicate and thus have good on press development property. As the R_{F}, a member having a CₙF₂ₙ₊₁CₘH₂ₘCOO— skeleton is particularly preferable from the standpoint of preventing the blur of ink, and a member having two or more CₙF₂ₙ₊₁CₘH₂ₘCOO— skeletons per molecule is more preferable, wherein n is an integer of 2 or more, and m is an integer of 1 or more.

Specific examples (F-1) to (F-19) of the organic fluorine compound preferably used in the invention are set forth below, but the invention should not be construed as being limited thereto.

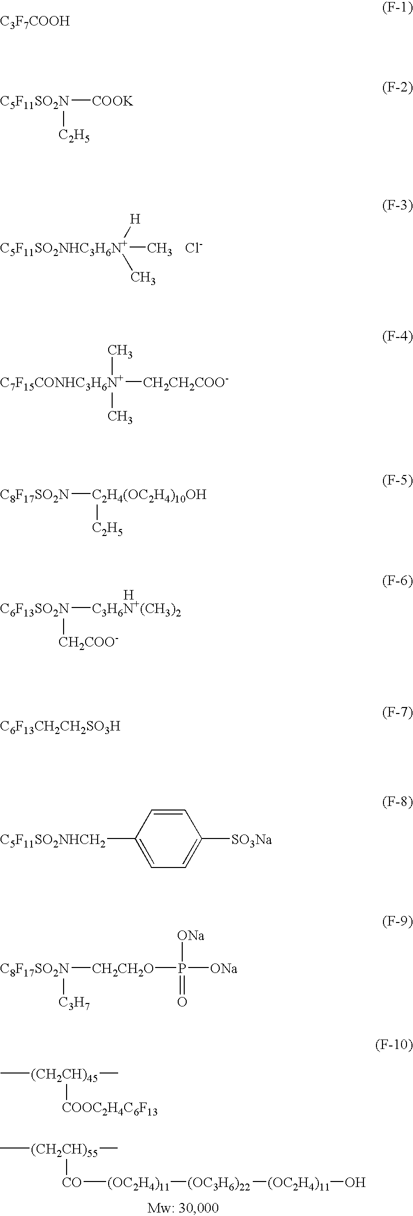

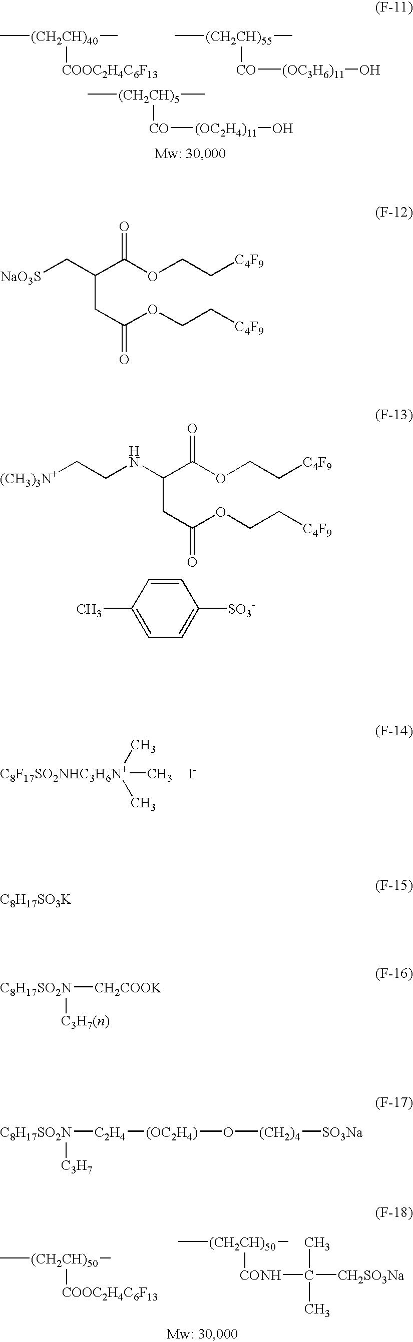

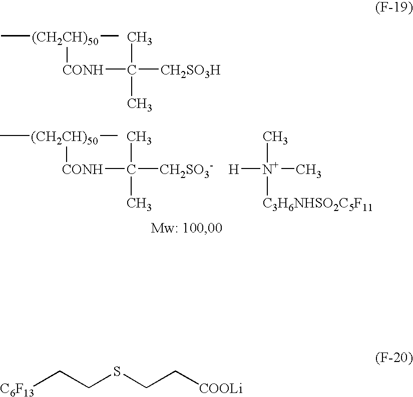

As the organic fluorine compound according to the invention, a fluorine-based polymer compound may also be used. Particularly, a fluorine-based polymer compound having a surface active effect and being water-soluble (hereinafter, also referred to as a “fluorine-based polymer surfactant”) is preferable.

Specific examples of the fluorine-based polymer surfactant include a copolymer of an acrylate having a fluoroaliphatic group or a methacrylate having a fluoroaliphatic group and a poly(oxyalkylene)acrylate or a poly(oxyalkylene)methacrylate. In the copolymer, the content of the monomer unit of the acrylate or methacrylate having a fluoroaliphatic group is preferably from 7% to 60% by weight based on the weight of the copolymer, and the molecular weight of the copolymer is preferably 3,000 to 100,000 in terms of weight average molecular weight.

The fluoroaliphatic group preferably has from 3 to 20 carbon atoms, may be straight-chain or branched, contains 40% by weight or more of fluorine and has at least three carbon atoms sufficiently fluorinated at the terminal. Specific examples of the acrylate or methacrylate having a fluoroaliphatic group include N-butylperfluorooctanesulfonamidoethyl acrylate, N-propylperfluorooctanesulfonamidoethyl acrylate and methylperfluorooctanesulfonamidoethyl acrylate. The molecular weight of the polyoxyalkylene group in the poly(oxyalkylene)acrylate or methacrylate is preferably from 200 to 3,000. Examples of the oxyalkylene group include an oxyethylene group, an oxypropylene group and an oxybutylene group, preferably an oxyethylene group or an oxypropylene group. For example, an acrylate or methacrylate having from 8 to 15 moles of oxyethylene groups added is used. If desired, the terminal of the polyoxyalkylene group may be added, for example, with a dimethyl siloxane group to restrain the foaming property.

The fluorine-based polymer surfactant is commercially available, and such a commercial product can be used in the invention. Two or more fluorine-based polymer surfactants may be used in combination.

Examples of the commercial products include Surflon S-111, S-112, S-113, S-121, S-131, S-141, S-145, S-381 and S-382 produced by Asahi Glass Co., Ltd., Megafac F-110, F120, F-142D, F-150, F-171, F177 and F781 produced by Dainippon Ink & Chemicals, Inc., Fluorad FC-93, FC-95, FC-98, FC-129, FC135, FX-161, FC170C, FC-171 and FC176 produced by Sumitomo 3M Ltd., FT-248, FT-448, FT-548, FT-624, FT-718 and FT-738 produced by Bayer Japan Ltd., and Zonyl FSA produced by E. I. du Pont de Nemours & Co.

(Combination Use with Hydrophilic Resin)

According to the invention, the components described above may be mixed with a hydrophilic resin to form an ink-receptive layer. The combination use with the hydrophilic resin further improves the stain resistance and the prevention of the blur of ink.

The hydrophilic resin is not particularly restricted as long as it is a water-soluble resin and includes, for example, a water-soluble cellulose having carboxylic acid or a salt thereof (for example, carboxymethyl cellulose), an acrylic or methacrylic polymer or a copolymer thereof, a hydrophilic acrylic, methacrylic, vinyl or styrene resin having a sulfonic acid group or a salt thereof, a hydrophilic resin containing an amido group, for example, polyacrylamide or polyvinyl pyrrolidone, a hydrophilic resin having an amino group, for example, polyallylamine, and a hydrophilic resin having a phosphoric acid or a salt thereof, for example, a phosphoric acid-modified starch described in JP-A-62-97892. The combination use with the hydrophilic resin further improves the ink repellency in the non-image area.

In the ink-receptive layer in the embodiment (1) according to the invention, the content of the particle of an organic polymer is in a range from 100 to 3,000 mg/m², preferably from 200 to 2,500 mg/m², the content of the compound including a fluorine atom is in a range from 0.2 to 250 mg/m², preferably from 0.5 to 100 mg/m², and the content of the hydrophilic resin is in a range from 1.0 to 2,000 mg/m², preferably from 50.0 to 1,000.0 mg/m².

In the ink-receptive layer in the embodiment (2) according to the invention, the content of the particle of an organic polymer including a fluorine atom is in a range from 100 to 3,000 mg/m², preferably from 200 to 2,500 mg/m², the content of the compound including a fluorine atom is in a range from 0 to 500 mg/m², preferably from 0 to 200 mg/m², and the content of the hydrophilic resin is in a range from 1.0 to 2,000 mg/m², preferably from 50.0 to 1,000.0 mg/m².

The ink-receptive layer also preferably contains a compound having an onium group. The compound having an onium group is described in detail in JP-A-2000-10292 and JP-A-2000-108538. Further, a compound selected from polymer compounds having a structural unit as represented by a poly(p-vinylbenzoic acid) in their molecule may be used. Specific examples of the polymer compound include a copolymer of p-vinylbenzoic acid and vinylbenzyltriethylammonium salt and a copolymer of p-vinylbenzoic acid and vinylbenzyltrimethylammonium chloride.

Also, a copolymer containing a repeating unit having at least one ethylenic unsaturated bond and a repeating unit having at least one functional group which interacts with the surface of support described in JP-A-2005-125749 is preferable.

Of these compounds, a polymer having a sulfonate skeleton is particularly preferable from the standpoint of the prevention of the blur of ink and stain resistance.

### [Ink]

In the invention, inkjet ink is used for forming the image area (hydrophobic ink-receptive region) of a lithographic printing plate. From the standpoint of ejection property, the ink preferably has viscosity in a range of 1 to 1,000 mPa·s and surface tension in a range of 1 to 100 mN/m at temperature of ejection. More preferably, the viscosity is in a range of 1 to 100 mPa·s and the surface tension is in a range of 1 to 80 mN/m at the temperature of ejection. A solution in which a polymer is dissolved is preferable as the ink.

[Ink in which Polymer is Dissolved in Organic Solvent]

In the invention, a polymer preferably used in an ink composition of ink (hereinafter, also referred to as a “polymer-dissolved type ink”) in which the polymer is dissolved in an organic solvent is a polymer or a copolymer having an acidic group. Examples of the acidic group include a carboxylic acid group, a sulfonic acid group and a phosphoric acid group, and a carboxylic acid group is particularly preferable.

The polymer or copolymer is preferably a polymer obtained by polymerization of an unsaturated double bond, for example, an acrylic or methacrylic polymer. The monomer having an acidic group is preferably acrylic acid, methacrylic acid, maleic acid, maleic anhydride, fumaric acid, fumaric anhydride or 2-acrylamido-2-methyl-1-propanesulfonic acid.

A part of the acidic group may be a salt structure and particularly, a salt of the acid with ammonia, a primary amine, a secondary amine, a tertiary amine or a quaternary ammonium compound is preferable.

The monomer having an acidic group may be copolymerized with other monomer. Examples of the monomer to be copolymerized include an acrylate, a methacrylate, a styrene monomer, a vinyl monomer and an acrylonitrile.

The weight average molecular weight of the polymer is preferably from 5,000 to 200,000. The polymer can be added in an amount of 2 to 50% by weight to the ink composition.

The solvent used in the ink composition is preferably water. Water is added in an amount of 5 to 90% by weight in the composition of the polymer-dissolved type ink. Also, an alcohol or an ether compound thereof can be added in an amount of 0.1 to 80% by weight of the polymer-dissolved type ink. Preferable specific examples of the alcohol or ether compound thereof include an alcohol, for example, methanol, ethanol, propanol, ethylene glycol, propylene glycol or diethylene glycol and ethers thereof.

The ink composition may contain a coloring agent, for example, a pigment or a dye, or a surface tension controlling agent, for example, a surfactant, if desired, as other component.

In the lithographic printing plate precursor according to the invention, the image area can be formed using any of these inks.

### [Drawing by Inkjet Recording System]

The inkjet recording system includes a continuous system wherein ink droplets are continuously ejected and divided into ink droplets for recording and ink droplets not for recording by an electric field or the like, and the ink droplets for recording are deposited on a medium and a on-demand system wherein only ink droplets required for recording are ejected from a nozzle. The on-demand system includes a thermal system (bubble system) ejecting ink droplets using pressure of bubbles generated by abrupt heating of the ink and a piezo system using a piezo element (piezoelectric element). The piezo system is classified into a direct mode type and a share mode type according to the direction of distortion generated by the applied voltage. The on-demand system also includes an electrostatic system wherein ink or particles included in ink are electrically charged and the ejection of ink is electrostatically controlled and a solid inkjet recording system wherein solid ink is heated to melt and ejected. These inkjet recording systems are described in detail, for example, in Inkjet Printer Gijutu to Zairyo (Technology and Material of Inkjet Printer), CMC Publishing, Inc. (Jul. 31, 1998) and Saishin Inkjet Gijutu Know-How Shu (Know-How in Latest Inkjet Technology), Technical Information Institute Co., Ltd. (Jun. 24, 2005). In the invention, any of the systems can be preferably used without limitation.

### [Fixing and Gum Coating]

The ink composition drawn by the inkjet recording system is dried to remove the solvent in the ink. The drying can be conducted naturally, but air blast drying is preferable. The ink composition is firmly fixed on the surface of the lithographic printing plate precursor by heating or exposure to light.

The resulting printing plate may be used as it is, or may be subjected to a development processing with an aqueous solution containing a surfactant and/or a hydrophilic resin, if desired. As to the development processing of the ink-receptive layer containing a fluorine atom, it is found that when it is developed with dampening water and/or printing ink on a printing machine, the printing ink hardly adheres on the ink-receptive layer at the printing and therefore, it is preferred to develop the region not impacted with the ink droplet of the ink-receptive layer with an aqueous solution (hereinafter, also referred to as a pre-developer) containing a surfactant and/or a hydrophilic resin.

The printing plate thus-obtained can be used for conventional printing using a lithographic printing machine.

### (Hydrophilic Resin)

The hydrophilic resin includes a water-soluble polymer compound. The water-soluble polymer compound includes, for example, gum arabic, a cellulose derivative (for example, carboxymethyl cellulose, arboxymethyl cellulose, methyl cellulose, hydroxypropyl cellulose or methyl propyl cellulose) or a modified product thereof, polyvinyl alcohol or a derivative thereof, polyvinyl pyrrolidone, polyacrylamide, a copolymer of acrylamide, a copolymer of vinyl methyl ether/maleic anhydride, a copolymer of vinyl acetate/maleic anhydride, a copolymer of styrene/maleic anhydride, a water-soluble soybean polysaccharide, a starch derivative (for example, dextrin, enzyme-decomposed dextrin, hydroxypropylated enzyme-decomposed dextrin, carboxydimethylated starch, phosphorylated starch or cyclodextrin), pllulan or a derivative thereof and hemicellulose extracted from soybean. Among them, gum arabic, a starch derivative, for example, dextrin, carboxymethyl cellulose or a soybean polysaccharide is preferably used. The content of the water-soluble polymer compound in the pre-developer is preferably from 0.1 to 25.0% by weight, more preferably from 0.3 to 20.0% by weight.

### (Surfactant)

As the surfactant, an anionic, cationic, nonionic or amphoteric surfactant is preferable.

Particularly, an anionic surfactant or a nonionic surfactant is preferable. The anionic surfactant includes, for example, a fatty acid salt, an abietic acid salt, a hydroxyalkanesulfonic acid salt, an alkanesulfonic acid salt, a dialkylsulfosuccinic acid salt, a straight-chain alkylbenzenesulfonic acid salt, a branched alkylbenzenesulfonic acid salt, an alkylnaphthalenesulfonic acid salt, an alkylphenoxypolyoxy ethylene propylsulfonic acid salt, a polyoxyethylene alkylsulfophenyl ether salt, N-methyl-N-oleyltaurine sodium salt, an N-alkylsulfosuccinic acid monoamide disodium salt, a petroleum sulfonic acid salt, sulfated castor oil, sulfated beef tallow oil, a sulfate ester slat of fatty acid alkyl ester, an alkyl sulfate ester salt, a polyoxyethylene alkyl ether sulfate ester salt, a fatty acid monoglyceride sulfate ester salt, a polyoxyethylene alkyl phenyl ether sulfate ester salt, a polyoxyethylene styryl phenyl ether sulfate ester salts, an alkyl phosphate ester salt, a polyoxyethylene alkyl ether phosphate ester salt, a polyoxyethylene alkyl phenyl ether phosphate ester salt, a partially saponified product of styrene-maleic anhydride copolymer, a partially saponified product of olefin-maleic anhydride copolymer and a naphthalene sulfonic acid salt formalin condensate. Among them, a dialkylsulfosuccinic acid salt, an alkyl sulfate ester salt and an alkylnaphthalenesulfonic acid salt are particularly preferably used.

The nonionic surfactant includes, for example, a polyoxyethylene alkyl ether, a polyoxyethylene alkylphenylether, a glycerin fatty acid partial ester, a sorbitan fatty acid partial ester, a pentaerythritol fatty acid partial ester, a propylene glycol monofatty acid ester, a sucrose fatty acid partial ester, a polyoxyethylene sorbitan fatty acid partial ester, a polyoxyethylene castor oil ether, a polyoxyethylene sorbitol fatty acid partial ester, a polyethylene glycol fatty acid ester, a polyglycerin fatty acid partial ester, a polyoxyethylene glycerin fatty acid partial ester, a fatty acid diethanolamide, an N,N-bis-2-hydroxyalkylamine, a polyoxyethylene alkylamine, a triethanolamine fatty acid ester and a trialylamine oxide. Among them, a polyoxyethylene alkyl ether, a polyoxyethylene polyoxypropylene block copolymer and a polyoxyethylene castor oil ether are preferably used.

Further, an oxyethylene adduct of acetylene glycol type or acetylene alcohol type or a fluorine-based or silicon-based nonionic or anionic surfactant can also be used.

The surfactants may be used as a mixture. For example, a combination of two or more anionic surfactants different from each other or a combination of an anionic surfactant and a nonionic surfactant is preferable. It is preferred to appropriately select the surfactant in consideration of the effect on the environment. The amount of the surfactant used is not particularly restricted and preferably from 0.01 to 20% by weight in the pre-developer.

### EXAMPLES

The present invention will be described in more detail with reference to the following examples, but the invention should not be construed as being limited thereto. In the examples, the term “part” means part by weight.

### [Formation of Aluminum Support Having Hydrophilic Grain]

### <Aluminum Plate>

A molten metal was prepared using an aluminum alloy containing 0.06% by weight of Si, 0.30% by weight of Fe, 0.005% by weight of Cu, 0.001% by weight of Mn, 0.001% by weight of Mg, 0.001% by weight of Zn and 0.03% by weight of Ti, with the balance of Al and inevitable impurities. The molten metal was subjected to a molten treatment and filtration, and then cast by a DC casting method to produce an ingot having a thickness of 500 mm and a width of 1200 mm. The surface of ingot was scraped by a thickness of 10 mm on average by a surface-scraping machine, and then the ingot was kept at 550° C. for about 5 hours. After the temperature thereof lowered to 400° C., the ingot was rolled by a hot rolling machine to produce a rolled plate having a thickness of 2.7 mm. Further, the plate was subjected to a heat treatment at 500° C. by a continuous annealing machine and then finished by cold rolling so as to have a thickness of 0.24 mm, thereby obtaining an aluminum plate of JIS A 1050. The aluminum plate was cut in a width of 1030 mm and then subjected to the surface treatment described below.

### <Surface Treatment>

Surface treatment was performed by continuously conducting following treatments (a) to (j). After each treatment and water washing, the plate was squeegeed between nip rollers.

### (a) Mechanical Surface Roughening Treatment

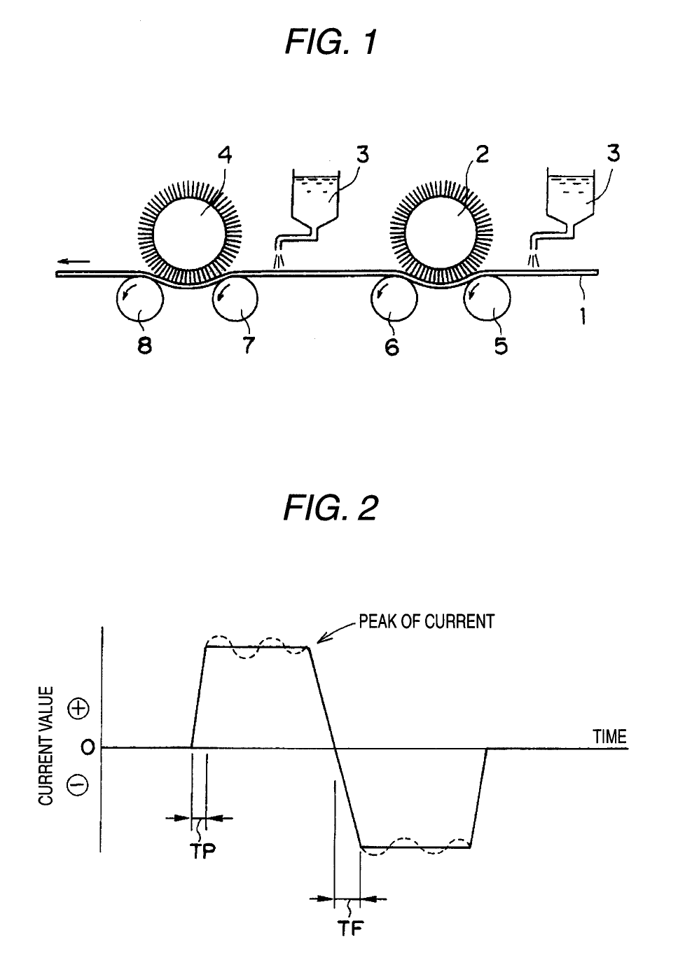

Mechanical surface roughening treatment of the aluminum plate was conducted by means of rotating roller-form nylon brushes while supplying a suspension of an abrasive (pumice) in water having specific gravity of 1.12 as an abrasion slurry solution to the surface of the aluminum plate using an apparatus as shown in FIG. 1. In FIG. 1, 1 represents an aluminum plate, 2 and 4 represent brush rollers, 3 represents an abrasive slurry, and 5, 6, 7 and 8 represent supporting rollers. The abrasive had an average particle size of 40 μm and a maximum particle size of 100 μm. The material of the nylon brush was 6-10 nylon and the brush has a bristle length of 50 mm and a bristle diameter of 0.3 mm. The nylon brush was made by making holes in a stainless steel cylinder having a diameter of 300 mm and densely filling the brush bristles. Three of the rotating nylon brushes were used. Two supporting rollers (each having a diameter of 200 mm) were placed apart from each other at a distance of 300 mm under the brush rollers. The brush rollers were pressed against the aluminum plate till the load applied to a driving motor for rotating the brush became 7 kw greater than the load before pressing the brush rollers against the aluminum plate. The rotating direction of the brush was same as the moving direction of the aluminum plate. The rotation number of the brush was 200 rpm.

### (b) Alkali Etching Treatment

Etching treatment of the aluminum plate was conducted by spraying an aqueous sodium hydroxide solution (sodium hydroxide concentration: 2.6% by weight, aluminum ion concentration: 6.5% by weight) having temperature of 70° C. to dissolve the aluminum plate in an amount of 6 g/m². Subsequently, the plate was washed with water by spraying.

### (c) Desmut Treatment

Desmut treatment of the aluminum plate was conducted by spraying an aqueous 1% by weight nitric acid solution (containing 0.5% by weight of aluminum ion) having temperature of 30° C. Subsequently, the plate was washed with water by spraying. The aqueous nitric acid solution used for the desmut treatment was a waste solution from the step of (d) electrochemical surface roughening treatment using an alternating current in an aqueous nitric acid solution described below.

### (d) Electrochemical Surface Roughening Treatment

Electrochemical surface roughening treatment of the aluminum plate was continuously conducted by applying 60 Hz alternating current voltage. The electrolyte used was an aqueous solution containing 10.5 g/liter of nitric acid (containing 5 g/liter of aluminum ion and 0.007% by weight of ammonium ion) and the electrolyte temperature was 50° C. The electrochemical surface roughening treatment was conducted using an alternating current source, which provided a trapezoidal rectangular wave alternating current having a waveform shown in FIG. 2, wherein the TP which was the time required for the current value to increase from zero to a peak was 0.8 msec and the duty ratio was 1:1, and using a carbon electrode as a counter electrode. A ferrite was used as an auxiliary anode. The electrolytic bath shown in FIG. 3 was used. The current density was 30 A/dm² in terms of peak value, and the electric quantity was 220 C/dmm² in terms of the total electric quantity at the time when the aluminum plate was functioning as an anode. To the auxiliary anode, 5% of the current flowing from the electric source was divided. Subsequently, the plate was washed with water by spraying.

### (e) Alkali Etching Treatment

Etching treatment of the aluminum plate was conducted at 32° C. by spraying an aqueous solution having a sodium hydroxide concentration of 26% by weight and an aluminum ion concentration of 6.5% by weight to dissolve the surface of aluminum plate in an amount of 0.25 g/m². Thus, the smut component mainly comprising aluminum hydroxide formed in the precedent step of (d) electrochemical surface roughening treatment using an alternating current was removed and an edge portion of the pit formed was dissolved to smoothen the edge portion. Subsequently, the plate was washed with water by spraying.

### (f) Desmut Treatment

Desmut treatment of the aluminum plate was conducted by spraying an aqueous 15% by weight nitric acid solution (containing 4.5% by weight of aluminum ion) having temperature of 30° C., followed by washing with water by spraying. The aqueous nitric acid solution used for the desmut treatment was a waste solution from the step of (d) electrochemical surface roughening treatment using an alternating current in an aqueous nitric acid solution described above.

### (g) Electrochemical Surface Roughening Treatment

Electrochemical surface roughening treatment of the aluminum plate was continuously conducted by applying 60 Hz alternating current voltage. The electrolyte used was an aqueous solution containing 7.5 g/liter of hydrochloric acid (containing 5 g/liter of aluminum ion) and the solution temperature was 35° C. The electrochemical surface roughening treatment was conducted using an alternating current source, which provided a trapezoidal rectangular wave alternating current having a waveform shown in FIG. 2, wherein the TP which is the time required for the current value to increase from zero to a peak was 0.8 msec and the duty ratio was 1:1, and using a carbon electrode as a counter electrode. A ferrite was used as an auxiliary anode. The electrolytic bath shown in FIG. 3 was used. The current density was 25 A/dm² in terms of peak value, and the electric quantity was 50 C/dmm² in terms of the total electric quantity at the time when the aluminum plate was functioning as an anode. Subsequently, the plate was washed with water by spraying.

### (h) Alkali Etching Treatment

Etching treatment of the aluminum plate was conducted at 32° C. by spraying an aqueous solution having a sodium hydroxide concentration of 26% by weight and an aluminum ion concentration of 6.5% by weight to dissolve the aluminum plate in an amount of 0.10 g/m². Thus, the smut component mainly comprising aluminum hydroxide formed in the precedent step of (g) electrochemical surface roughening treatment using an alternating current was removed and an edge portion of the pit formed was dissolved to smoothen the edge portion. Subsequently, the plate was washed with water by spraying.

### (i) Desmut Treatment

Desmut treatment of the aluminum plate was conducted by spraying an aqueous 25% by weight sulfuric acid solution (containing 0.5% by weight of aluminum ion) having temperature of 60° C., followed by washing with water by spraying.

### (h) Anodic Oxidation Treatment

Anodic oxidation treatment of the aluminum plate was conducted using an anodic oxidation device having the structure shown in FIG. 4 to prepare a support for a lithographic printing plate precursor of Example 1. As the electrolyte supplied into the first and second electrolyzing sections, sulfuric acid was used. Specifically, the electrolyte has sulfuric acid concentration of 170 g/liter (containing 0.5% by weight of aluminum ion) and temperature of 38° C. Subsequently, the plate was washed with water by spraying. The final amount of the anodic oxide film formed was 2.7 g/m².

In the support thus-obtained, a center line average roughness was 0.55 μm, an average wavelength of large wave was 65 μm, an average aperture size of medium wave was 1.4 μm, an average aperture size of small wave was 0.14 μm, and a ratio of the depth to the average aperture size of the small wave was 0.46.

### (k) Alkali Metal Silicate Treatment

Alkali metal silicate treatment (silicate treatment) of the aluminum plate subjected to the anodic oxidation treatment was conducted by immersing the aluminum plate in a treatment bath containing an aqueous 2.5% by weight sodium silicate No. 3 solution having temperature of 70° C. for 7 seconds. Subsequently, the plate was washed by spraying well water, whereby Support 1 subjected to the surface silicate hydrophilizing treatment was prepared. The amount of the silicate was measure using X ray fluorescence and found to be 9.0 mg/m².

### [Preparation of Support Having Hydrophilic Sol-Gel Layer]

A coating solution for hydrophilic layer having the composition shown below was coated on the silicate treated layer of Support 1 using a bar and dried in an oven at 80° C. for 10 minutes to prepare a hydrophilic layer having a dry coating weight of 3.0 g/m², thereby preparing Support 2.

<Coating solution for hydrophilic layer>

| | |
|---|---|
| 20% by weigh aqueous dispersion of colloidal | 100 g |
| silica (Snowtex C, produced by Nissan Chemical | |
| Industries, Ltd.) | |
| Sol-gel solution shown below | 500 g |
| 5% by weigh aqueous solution of anionic | 30 g |
| surfactant (Nikkol OTP-75, produced by Nikko | |
| Chemicals Co., Ltd.) | |
| Purified water | 450 g |

### <Sol-Gel Solution>

To a mixture of 19.2 g of ethyl alcohol, 0.86 g of acetylacetone, 0.98 g of tetraethyl orthotitanate and 8.82 g of purified water were added 1.04 g of tetramethoxysilane (produced by Tokyo Chemical Industry Co., Ltd.) and 0.34 g of a hydrophilic polymer having a silane coupling group at the terminal to mix, and the mixture was aged at room temperature for 2 hours, thereby preparing a sol-gel solution.

### <Synthesis of Hydrophilic Polymer Having Silane Coupling Group at Terminal>

In a three-necked flask were placed 25 g of acrylamide, 3.5 g of 3-mercaptopropyltrimethoxysilane and 51.3 g of dimethylformamide, and the mixture was heated to 65° C. under nitrogen gas stream and then 0.25 g of 2,2′-azobis(2,4-dimethylvaleronitrile) was added thereto to initiate the reaction. After stirring for 6 hours, the mixture was cooled to room temperature and poured in 1.5 liters of ethyl acetate to deposit a solid. Subsequently, the mixture was filtered, and the solid was thoroughly washed with ethyl acetate and dried (yield: 21 g). The solid was determined by GPC (polystyrene standard) and found to be a polymer having a weight average molecular weight of 5,000.

### [Preparation of Ink-Receptive Layer]

### <Synthesis of Particle of Organic Polymer 1 (Including Fluorine Atom)>

Into a 5-liter reaction vessel equipped with a stirrer, a nitrogen gas inlet and a condenser and heated with a hot-water bath was introduced a mixture of 49 parts of deionized water, 0.05 parts of NP25EO, 0.25 parts of NPS25EO and 0.35 parts of sodium disulfite. The reaction vessel was deaerated with nitrogen and heated at 67° C. and then were simultaneously introduced therein a pre-emulsion of 45 parts of water, 90 parts of MMA, 10 parts of TRIFEMA, 0.45 parts of NP25EO and 2.25 parts of NPS25EO and a catalyst solution containing 0.35 parts of ammonium persulfate added to 6 parts of deionized water over a period of 4 hours and 30 minutes. During the introduction of the pre-emulsion and catalyst solution, the temperature of the hot-water bath was kept at 67° C. and the stirring rate was maintained at 200 rpm. After the completion of the introduction, the temperature of the hot-water bath was kept at 67±1° C. for one and a half hours. The dispersion system was cooled, filtered and 20% aqueous ammonia was added thereto to adjust pH to 9. Thereafter, deionized water was added to the dispersion system to prepare a solution having a solid content concentration of 10.0%. The particle size in the dispersion system was 140 nm.
TRIFEMA: 2,2,2-Trifluoroethyl Methacrylate
NP25EO: Oxyethylenated nonylphenol containing 25 moles of ethyleneoxide
NPS25EO: Oxyethylenated nonylphenolsulfate containing 25 moles of ethyleneoxide
MMA: Methyl methacrylate

### <Synthesis of Particle of Organic Polymer 2 (Not Including Fluorine Atom)>

Into a 5-liter reaction vessel equipped with a stirrer, a nitrogen gas inlet and a condenser and heated with a hot-water bath was introduced a mixture of 49 parts of deionized water, 0.05 parts of NP25EO, 0.25 parts of NPS25EO and 0.35 parts of sodium disulfite. The reaction vessel was deaerated with nitrogen and heated at 67° C. and then were simultaneously introduced therein a pre-emulsion of 45 parts of water, 100 parts of MMA, 0.45 parts of NP25EO and 2.25 parts of NPS25EO and a catalyst solution containing 0.35 parts of ammonium persulfate added to 6 parts of deionized water over a period of 4 hours and 30 minutes. During the introduction of the pre-emulsion and catalyst solution, the temperature of the hot-water bath was kept at 67° C. and the stirring rate was maintained at 200 rpm. After the completion of the introduction, the temperature of the hot-water bath was kept at 67±1° C. for one and a half hours. The dispersion system was cooled, filtered and 20% aqueous ammonia was added thereto to adjust pH to 9. Thereafter, deionized water was added to the dispersion system to prepare a solution having a solid content concentration of 10.0%. The particle size in the dispersion system was 140 nm.

[Self-water dispersible resin particle 1 (including fluorine
atom)]

| | |
|---|---|
| Acrylic acid resin A | 20 parts |
| (methyl methacrylate/TRIFEMA/acrylic | |
| acid/methacrylic acid = 67/10/10/13 in molar | |
| ratio, acid value: 158, glass transition | |
| temperature: 107° C.) | |
| Trisacetylacetonatoaluminum (crosslinking | 1.8 parts |
| rate: 30% equivalent) | |
| Triethanolamine (neutralizing rate: 70% | 5.9 parts |
| equivalent) | |
| Methyl ethyl ketone | 30 parts |
| Isopropyl alcohol | 20 parts |

The components described above were mixed and dissolved to prepare a synthetic resin solution. To the synthetic resin solution was dropwise added with stirring a mixed solution of 3 parts of glycerine and 125 parts of ion-exchanged water at a rate of 5 ml per minute to prepare a resin emulsion, followed by filtration using a filter of 0.5 μm to obtain Self-water dispersible resin particle 1. The particle size of the particle obtained was 95 nm.

[Self-water dispersible resin particle 2 (not including fluorine
atom)]

| | |
|---|---|
| Acrylic acid resin B | 20 parts |
| (methyl methacrylate/acrylic | |
| acid/methacrylic acid = 77/10/13 in molar | |
| ratio, acid value: 158, glass transition | |
| temperature: 107° C.) | |
| Trisacetylacetonatoaluminum (crosslinking | 1.8 parts |
| rate: 30% equivalent) | |
| Triethanolamine (neutralizing rate: 70% | 5.9 parts |
| equivalent) | |
| Methyl ethyl ketone | 30 parts |
| Isopropyl alcohol | 20 parts |

The components described above were mixed and dissolved to prepare a synthetic resin solution. To the synthetic resin solution was dropwise added with stirring a mixed solution of 3 parts of glycerine and 125 parts of ion-exchanged water at a rate of 5 ml per minute to prepare a resin emulsion, followed by filtration using a filter of 0.5 μm to obtain Self-water dispersible resin particle 2. The particle size of the particle obtained was 70 nm.

### Examples 1 to 4 and Comparative Examples 1 to 2

A solution having the composition shown below containing the particle of an organic polymer as shown in Table 1 below was coated on Support 1 and dried at 90° C. for 90 seconds. The coating amount was 1.0 g/m².

| | |
|---|---|
| Water | 100 parts |
| Solution of particle of organic polymer | 90 parts |
| Organic fluorine compound (F-20) | Shown in |
| | Table 1 |

### Comparative Example 3

A solution having the composition shown below was coated on Support 1 and dried at 90° C. for 90 seconds. The coating amount was 1.0 g/m².

| | |
|---|---|
| Water | 100 parts |
| Organic fluorine compound (F-20) | Shown in |
| | Table 1 |

### Examples 5 to 8 and Comparative Examples 4 to 6

A solution having the composition shown below containing the particle of an organic polymer as shown in Table 2 below was coated on Support 2 and dried at 90° C. for 90 seconds. The coating amount was 1.0 g/m².

| | |
|---|---|
| Water | 100 parts |
| Solution of particle of organic polymer | 90 parts |
| Organic fluorine compound (F-20) | Shown in |
| | Table 2 |

### [Preparation of Lithographic Printing Plate]

An ink composition having the composition shown below was thoroughly stirred and uniformly mixed to prepare ink for evaluation containing a polymer, a solvent and a dye.

Further, a developer having the composition shown below was prepared.

The ink for evaluation was ejected on the surface of the lithographic printing plate precursor described above under the conditions shown below and cured to form an image area thereby preparing a lithographic printing plate.

| | | |
|---|---|---|
| (Ink composition) | | |
| Ethyl lactate | 50 | g |
| n-Butanol | 46 | g |
| Copolymer of methyl methacrylate and | 3.5 | g |
| methacrylic acid (copolymerization ratio: | | |
| 70/30 in mole) | | |
| Oil Blue N | 0.5 | g |
| (Developer composition) | | |
| Water | 80 | parts |
| Sodium dodecylbenzenesulfonate | 10 | parts |
| Carboxymethyl cellulose (weight average | 10 | parts |
| molecular weight: 3.0 × 10⁴) | | |

### (Inkjet Image-Drawing)

The image-drawing was performed on each of the lithographic printing plate precursors of Examples 1 to 8 and Comparative Examples 1 to 6 using the ink composition described above and an ink jet printer (SP-300V, produced by Roland DG Corp.) equipped with a piezo-type head. Then, the developer described above was coated on the lithographic printing plate precursor. With the lithographic printing plate thus-prepared, a diameter of the minimum dot formed was measured by an optical microscope.

In the examples, the ejection conditions of inkjet were selected with the aim of obtaining an ink dot diameter of 31 to 40 μm capable of forming an image having high resolution and being free from lack in the 100% image area. The reason for this is that when the dot diameter decreases 30 μm or less, openings in the solid portion begin to outstand and when it increases larger than 40 μm, the image quality tends to degrade. The results obtained are shown in Tables 1 and 2.

Further, the unevenness in 100% image area (shown in Table 1) and the interference of ink droplet impact in the solid area (shown in Table 2) were evaluated and determined they were permissible level or impermissible level as the product. The results obtained are also shown in Tables 1 and 2, respectively.

TABLE 1

| | Lithographic Printing Plate Precursor | | | Performances | |
|---|---|---|---|---|---|
| | | Particle of | | Dot Diameter | Unevenness in |
| | Support | Organic Polymer | (F-20) | (μm) | 100% Image Area |
| Example 1 | Support 1 | Particle of | — | 35.0 μm | Permissible |
| | | Organic Polymer 1 | | | |
| Example 2 | Support 1 | Self-water | — | 36.0 μm | Permissible |
| | | Dispersible Resin | | | |
| | | Particle 1 | | | |
| Example 3 | Support 1 | Particle of | 1.0 part by | 39.5 μm | Permissible |
| | | Organic Polymer 2 | weight | | |
| Example 4 | Support 1 | Self-water | 1.0 part by | 38.5 μm | Permissible |
| | | Dispersible Resin | weight | | |
| | | Particle 2 | | | |
| Comparative | Support 1 | Particle of | — | 80.0 μm | Permissible |
| Example 1 | | Organic Polymer 2 | | | |
| Comparative | Support 1 | Self-water | — | 90.0 μm | Permissible |
| Example 2 | | Dispersible Resin | | | |
| | | Particle 2 | | | |
| Comparative | Support 1 | — | 1.0 part by | 35.0 μm | Impermissible |
| Example 3 | | | weight | | |

TABLE 2

| | | | | Performances | |
|---|---|---|---|---|---|
| | Lithographic Printing Plate Precursor | | | | Interference of |
| | | Particle of | | Dot Diameter | Ink Droplet Impact |
| | Support | Organic Polymer | (F-20) | (μm) | (solid area) |
| Example 5 | Support 2 | Particle of | — | 37.0 μm | Permissible |
| | | Organic Polymer 1 | | | |
| Example 6 | Support 2 | Self-water | — | 38.0 μm | Permissible |
| | | Dispersible Resin | | | |
| | | Particle 1 | | | |
| Example 7 | Support 2 | Particle of | 1.0 part by | 40.0 μm | Permissible |
| | | Organic Polymer 2 | weight | | |
| Example 8 | Support 2 | Self-water | 1.0 part by | 39.5 μm | Permissible |
| | | Dispersible Resin | weight | | |
| | | Particle 2 | | | |
| Comparative | Support 2 | Particle of | — | 90.0 μm | Permissible |
| Example 4 | | Organic Polymer 2 | | | |
| Comparative | Support 2 | Self-water | — | 95.0 μm | Permissible |
| Example 5 | | Dispersible Resin | | | |
| | | Particle 2 | | | |
| Comparative | Support 2 | — | 1.0 part by | 38.0 μm | Impermissible |
| Example 6 | | | weight | | |

As is apparent from the results shown in Tables 1and 2, it can be seen that the image having the desired dot diameter can be formed by forming the ink image using the lithographic printing plate precursor according to the invention. Also, it is found that the problem of interference of ink droplet impact in the 100% image area (solid area) does not occur.

### Example 9

A solution having the composition shown below containing the particle of an organic polymer as shown below was coated on Support 1 and dried at 90° C. for 90 seconds. The coating amount was 1.0 g/m².

| | |
|---|---|
| Water | 100 parts |
| Solution of particle of organic polymer | 45 parts |
| (Particle of organic polymer 1) | |
| Solution of particle of organic polymer | 45 parts |
| (Particle of organic polymer 2) | |

### Example 10

A solution having the composition shown below containing the particle of an organic polymer as shown below was coated on Support 1 and dried at 90° C. for 90 seconds. The coating amount was 0.8 g/m².

| | |
|---|---|
| Water | 100 parts |
| Solution of particle of organic polymer | 80 parts |
| (Particle of organic polymer 2) | |

Further, a solution having the composition shown below containing the particle of an organic polymer as shown below was coated on the layer and dried at 90° C. for 90 seconds. The coating amount was 0.2 g/m².

| | |
|---|---|
| Water | 100 parts |
| Solution of particle of organic polymer | 10 parts |
| (Particle of organic polymer 1) | |

The evaluation was conducted in the same manner as in Example 1. The results obtained are shown in Table 3 below.

TABLE 3

Performances

| | | | Interference |
|---|---|---|---|
| | | | of Ink Droplet |
| | | Dot Diameter | Impact (solid |
| | Support | (μm) | area) |
| Example 9 | Support 1 | 34.0 μm | Permissible |
| Example 10 | Support 1 | 33.0 μm | Permissible |
| Example 1 | Support 1 | 35.0 μm | Permissible |

### Example 11

The ink was ejected by inkjet on the lithographic printing plate precursor of Example 1 in the same manner as in Example 1 and without conducting development, directly mounted on a printing machine. The printing machine used was a Mitsubishi Dia-type F2 printing machine (produced by Mitsubishi Heavy Industries, Ltd.). Printing was carried out using a 3% aqueous solution of dampening water (Ecolity-2, produced by Fuji Film Co., Ltd.) and red ink (DIC-GEOS (s)). After contacting a dampening roller with the plate at 10 revolutions, printing was initiated simultaneously with the application of the ink. The stain resistance was compared with Example 1. The results obtained are shown in Table 4 below.

TABLE 4

| | Stain Resistance |
|---|---|
| Example 11 | Lower limit of permissible level |
| Example 1 | Permissible level |

This application is based on Japanese Patent application JP 2007-082229, filed Mar. 27, 2007, the entire content of which is hereby incorporated by reference, the same as if fully set forth herein.

Although the invention has been described above in relation to preferred embodiments and modifications thereof, it will be understood by those skilled in the art that other variations and modifications can be effected in these preferred embodiments without departing from the scope and spirit of the invention.

What is claimed is:

1. A lithographic printing plate precursor comprising: a support; and an ink-receptive layer comprising a particle of an organic polymer and a compound comprising a fluorine atom.

2. A lithographic printing plate precursor comprising: a support; and an ink-receptive layer comprising a particle of an organic polymer comprising a fluorine atom.

3. The lithographic printing plate precursor as claimed in claim 1, wherein the support is an aluminum support having a hydrophilic surface.

4. The lithographic printing plate precursor as claimed in claim 2, wherein the support is an aluminum support having a hydrophilic surface.

5. The lithographic printing plate precursor as claimed in claim 1, wherein the ink-receptive layer comprises both a particle of an organic polymer comprising a fluorine atom and a particle of an organic polymer being free from a fluorine atom.

6. The lithographic printing plate precursor as claimed in claim 2, wherein the ink-receptive layer comprises both a particle of an organic polymer comprising a fluorine atom and a particle of an organic polymer being free from a fluorine atom.

7. The lithographic printing plate precursor as claimed in claim 2, wherein the ink-receptive layer comprising: a first layer comprising a particle of an organic polymer being free from a fluorine atom; and a second layer comprising a particle of an organic polymer comprising a fluorine atom, so that the support, the first layer and the second layer are provided in this order.

8. A printing method comprising:
ejecting imagewise inkjet ink by an inkjet recording system on the lithographic printing plate precursor as claimed in claim 1;
subjecting an area not ejected with the inkjet ink of the ink-receptive layer to development to prepare a lithographic printing plate;
mounting the lithographic printing plate on a printing machine; and
printing by supplying printing ink and dampening water,
wherein the development of the area not ejected with the inkjet ink of the ink-receptive layer is performed with an aqueous solution comprising at least one of a surfactant and a hydrophilic resin.

9. A printing method comprising:
ejecting imagewise inkjet ink by an inkjet recording system on the lithographic printing plate precursor as claimed in claim 2;
subjecting an area not ejected with the inkjet ink of the ink-receptive layer to development to prepare a lithographic printing plate;
mounting the lithographic printing plate on a printing machine; and
printing by supplying printing ink and dampening water,
wherein the development of the area not ejected with the inkjet ink of the ink-receptive layer is performed with an aqueous solution comprising at least one of a surfactant and a hydrophilic resin.
